(19) United States
(12) Patent Application Publication
(10) Pub. No.: US 2025/0038159 A1
(43) Pub. Date: Jan. 30, 2025

(54) DISPLAY DEVICE AND MANUFACTURING METHOD OF DISPLAY DEVICE

(71) Applicant: Samsung Display Co., LTD., Yongin-si (KR)

(72) Inventor: Byeong Hoon CHO, Yongin-si (KR)

(73) Assignee: Samsung Display Co., LTD., Yongin-si (KR)

(21) Appl. No.: 18/665,907

(22) Filed: May 16, 2024

(30) Foreign Application Priority Data
Jul. 26, 2023 (KR) 10-2023-0097732

(51) Int. Cl. H01L 25/16; H01L 25/075; H01L 27/12; H01L 33/62

(52) U.S. Cl. CPC H01L 25/167; H01L 25/0753; H01L 27/124; H01L 33/62; H01L 2933/0016; H01L 2933/0066

(57) ABSTRACT

A display device including an internal area and a peripheral area surrounding at least a portion of the internal area includes a pixel-circuit layer disposed on a base layer and including lower lines, at least a portion of which form a pixel circuit, and sub-pixels disposed on the pixel-circuit layer and including a light emitting element electrically connected to the pixel circuit. The internal area includes a pixel area on which the sub-pixels are disposed, and an outer-dam area formed at a periphery of the pixel area. In the outer-dam area, at least another portion of the lower lines are stacked in a thickness direction of the base layer to form a protruding structure.

### CROSS-REFERENCE TO RELATED APPLICATION(S)

This application claims priority to and benefits of Korean patent application No. 10-2023-0097732 under 35 U.S.C. § 119, filed on Jul. 26, 2023, in the Korean Intellectual Property Office (KIPO), the entire contents of which are incorporated herein by reference.

### BACKGROUND

### 1. Technical Field

The disclosure relates to a display device and a method of manufacturing the display device.

### 2. Description of the Related Art

Recently, as interest in information display is increasing, research and development on display devices are continuously made.

### SUMMARY

The disclosure is to provide a display device and a method of manufacturing the display device that is capable of improving production yield and convenience.

The disclosure is to provide a display device and a method of manufacturing the display device that is capable of improving an alignment quality (e.g., degree of an alignment) by aligning more closely light emitting elements on an alignment electrode.

According to an embodiment, a display device including an internal area and a peripheral area surrounding at least a portion of the internal area may include a pixel-circuit layer disposed on a base layer and including lower lines, at least a portion of which forms a pixel circuit, and sub-pixels disposed on the pixel-circuit layer and including a light emitting element electrically connected to the pixel circuit. The internal area may include a pixel area on which the sub-pixels are disposed, and an outer-dam area formed at a periphery of the pixel area. In the outer-dam area, at least another portion of the lower lines may be stacked in a thickness direction of the base layer to form a protruding structure.

According to an embodiment, the outer-dam area may surround an edge of the pixel area and form a loop structure in a plan view.

According to an embodiment, the display device may further include a bank disposed on the pixel-circuit layer. An upper surface of the bank may be spaced apart from the base layer in the outer-dam area by a first distance and may be spaced apart from the base layer in the pixel area by a second distance. The first distance may be greater than the second distance.

According to an embodiment, the display device may further include a first electrode and a second electrode disposed on the pixel-circuit layer and spaced apart from each other. The light emitting element may be disposed between the first electrode and the second electrode.

According to an embodiment, the light emitting element may not be disposed in the outer-dam area so that the sub-pixels are not formed in the outer-dam area.

According to an embodiment, the lower lines may include a lower auxiliary electrode layer disposed on the base layer, at least a portion of which forms a first dam formation line, a first interlayer conductive layer disposed on the lower auxiliary electrode layer, at least a portion of which forms a second dam formation line, and a second interlayer conductive layer disposed on the first interlayer conductive layer, at least a portion of which forms a third dam formation line. The first dam formation line, the second dam formation line, and the third dam formation line may form the protruding structure.

According to an embodiment, the display device may further include a dummy pixel area disposed between the pixel area and the outer-dam area.

According to an embodiment, the light emitting element may not be disposed in the dummy pixel area. A dummy line may be disposed in the dummy pixel area.

According to an embodiment, the outer-dam area may include a first outer-dam area and a second outer-dam area spaced apart from each other. At least a portion of the dummy pixel area may be disposed between the first outer-dam area and the second outer-dam area.

According to an embodiment, the dummy pixel area may include a first dummy pixel area, a second dummy pixel area, and a third dummy pixel area, which are spaced apart from each other. The first outer-dam area may be disposed between the first dummy pixel area and the second dummy pixel area. The second outer-dam area may be disposed between the second dummy pixel area and the third dummy pixel area.

According to an embodiment, a display device may include a pixel-circuit layer disposed on a base layer, at least a portion of the pixel-circuit layer including a pixel circuit, a light emitting element layer disposed on the pixel-circuit layer and including a light emitting element electrically connected to the pixel circuit and a bank surrounding at least a portion of an area on which the light emitting element is disposed, a pixel area on which the light emitting element is disposed, a dummy pixel area surrounding at least a portion of the pixel area in a plan view and on which the light emitting element is not disposed, and an outer-dam area surrounding at least a portion of the dummy pixel area in a plan view. An upper surface of the bank may be spaced from the base layer by a first distance in the outer-dam area, and may be spaced from the base layer by a second distance in the dummy pixel area. The first distance may be greater than the second distance.

According to an embodiment, a manufacturing method of a display device including an internal area and a peripheral area surrounding at least a portion of the internal area may include forming an alignment-electrode layer including a first alignment electrode and a second alignment electrode and a bank on a pixel-circuit layer, supplying a light emitting element on the pixel-circuit layer, and aligning the light emitting element between the first alignment electrode and the second alignment electrode. The pixel-circuit layer may include a base layer and lower lines on the base layer. The internal area may include an outer-dam area formed at an edge of the internal area. In the outer-dam area, at least a portion of the lower lines may be stacked in a thickness direction of the base layer to form a protruding structure.

According to an embodiment, the supplying of the light emitting element may include providing ink including the light emitting element on the pixel-circuit layer, and providing a solvent on the pixel-circuit layer.

According to an embodiment, forming of the bank may include patterning the bank to form openings. The providing of the ink may include forming an ink area on which the ink is disposed. The ink area may cover the openings.

According to an embodiment, the providing of the solvent may include moving the light emitting element to each of the openings. A movement of the light emitting element may be restricted by the protruding structure.

According to an embodiment, in the providing of the solvent, an alignment signal may be supplied to the first alignment electrode and the second alignment electrode to form an electric field for maintaining a position of the light emitting element.

According to an embodiment, the internal area may include a pixel area. The providing of the solvent may include supplying the solvent entirely in the pixel area.

According to an embodiment, the providing of the ink may be performed by a first printing apparatus. The providing of the solvent may be performed by a second printing apparatus.

According to an embodiment, the providing of the ink may be performed by a printing apparatus. The providing of the solvent may be performed by a nozzle coater.

According to an embodiment, the manufacturing method may further include patterning a connection-electrode layer including a first connection electrode and a second connection electrode electrically connected to the light emitting element.

According to embodiments of the disclosure, a display device and a method of manufacturing the display device that may improve process yield, and convenience may be provided.

The disclosure is to provide a display device and a method of manufacturing the display device that is capable of improving an alignment quality (e.g., degree of an alignment) by aligning more closely light emitting elements on an alignment electrode.

### BRIEF DESCRIPTION OF THE DRAWINGS

FIG. 1 is a schematic perspective view illustrating a light emitting element according to an embodiment.

FIG. 2 is a schematic cross-sectional view illustrating a light emitting element according to an embodiment.

FIG. 3 is a schematic plan view illustrating a display device according to an embodiment.

FIG. 4 is a schematic cross-sectional view illustrating a stacked structure of a display device according to an embodiment.

FIGS. 5 and 6 are schematic drawings illustrating a display device according to an embodiment.

FIG. 7 is a schematic cross-sectional view illustrating a display device according to an embodiment.

FIGS. 8 to 10 are schematic drawings illustrating a display device including an outer-dam area according to an embodiment.

FIGS. 11 to 14 are schematic drawings illustrating a display device including an outer-dam area according to another embodiment.

FIGS. 15 to 17 are schematic drawings illustrating a display device including an outer-dam area according to another embodiment.

FIGS. 18 and 19 are flowcharts illustrating a manufacturing method of a display device according to an embodiment.

FIGS. 20 to 31 are schematic drawings of each process step illustrating a manufacturing method of a display device according to an embodiment.

### DETAILED DESCRIPTION OF THE EMBODIMENTS

It will be apparent to those skilled in the art that various modifications and variations can be made in the disclosure without departing from the spirit or scope of the disclosure, and specific embodiments are illustrated in the drawings and explained in the detailed description. Thus, it is intended that the disclosure covers the modifications and variations of disclosure provided they come in the scope of the disclosure and their equivalents.

Although the terms “first,” “second,” etc. may be used herein to describe various types of elements, these elements should not be limited by these terms. These terms are used to distinguish one element from another element. Thus, a first element discussed below could be termed a second element without departing from the teachings of the disclosure.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof. It is also noted that, as used herein, the terms “substantially,” “about,” and other similar terms, are used as terms of approximation and not as terms of degree, and, as such, are utilized to account for inherent deviations in measured, calculated, and/or provided values that would be recognized by one of ordinary skill in the art.

When an element, such as a layer, is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. To this end, the term “connected” may refer to physical, electrical, and/or fluid connection, with or without intervening elements. Also, when an element is referred to as being “in contact” or “contacted” or the like to another element, the element may be in “electrical contact” or in “physical contact” with another element; or in “indirect contact” or in “direct contact” with another element.

Spatially relative terms, such as “beneath,” “below,” “under,” “lower,” “above,” “upper,” “over,” “higher,” “side” (e.g., as in “sidewall”), and the like, may be used herein for descriptive purposes, and, thereby, to describe one elements relationship to another element(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

In the specification and the claims, the phrase “at least one of” is intended to include the meaning of “at least one selected from the group of” for the purpose of its meaning and interpretation. For example, “at least one of A and B” may be understood to mean “A, B, or A and B.” In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

Unless otherwise defined or implied herein, all terms (including technical and scientific terms) used have the same meaning as commonly understood by those skilled in the art to which this disclosure pertains. It will be further understood that terms, such as those defined in commonly used dictionaries, should be interpreted as having a meaning that is consistent with their meaning in the context of the relevant art and should not be interpreted in an ideal or excessively formal sense unless clearly defined in the specification.

The disclosure relates to a display device and a method of manufacturing the display device. Hereinafter, a display device and a method of manufacturing the display device according to embodiments will be described with reference to the accompanying drawings.

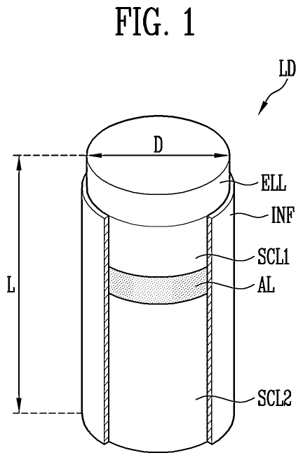

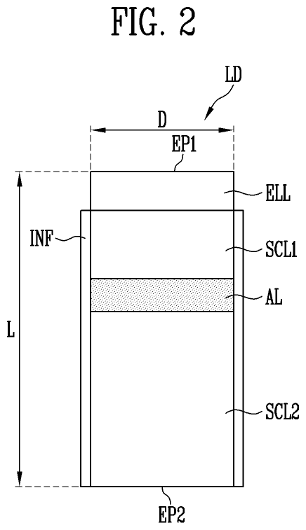

A light emitting element LD according to an embodiment will be described with reference to FIGS. 1 and 2. FIG. 1 is a schematic perspective view illustrating a light emitting element according to an embodiment. FIG. 2 is a schematic cross-sectional view illustrating a light emitting element according to an embodiment.

The light emitting element LD may be configured to emit light. The light emitting element LD may include a first semiconductor layer SCL1, a second semiconductor layer SCL2, and an active layer AL disposed between the first semiconductor layer SCL1 and the second semiconductor layer SCL2. According to an embodiment, the first semiconductor layer SCL1, the active layer AL, and the second semiconductor layer SCL2 may be sequentially stacked in a length direction L of the light emitting element LD. According to an embodiment, the light emitting element LD may further include an electrode layer ELL and an insulating layer INF.

The light emitting element LD may have various shapes. For example, the light emitting element LD may have a pillar shape extending in a direction. The pillar shape may include a rod-like shape or a bar-like shape that is long in the length direction L (e.g., with an aspect ratio greater than 1), such as a circular pillar or a polygonal pillar, but a shape of the light emitting element LD is not particularly limited.

The light emitting element LD may have a first end EP1 and a second end EP2. According to an embodiment, the first semiconductor layer SCL1 may be adjacent to a first end EP1 of the light emitting element LD, and the second semiconductor layer SCL2 may be adjacent to a second end EP2. According to an embodiment, the electrode layer ELL may be adjacent to the first end EP1.

The light emitting element LD may be manufactured by etching sequentially stacked semiconductor layers. The light emitting element LD may have a size ranging from nanoscale to microscale. For example, each of a diameter D (or width) of the light emitting element LD and a length L of the light emitting element LD may have nanoscale or microscale. However, the disclosure is not limited thereto.

The first semiconductor layer SCL1 may include a semiconductor of a first conductive type. The first semiconductor layer SCL1 may be disposed on the active layer AL, and the first semiconductor layer SCL1 and the second semiconductor layer SCL2 may include different types of semiconductor layers. For example, the first semiconductor layer SCL1 may include a P-type semiconductor layer. For example, the first semiconductor layer SCL1 may include at least one of InAlGaN, GaN, AlGaN, InGaN, AlN, and InN, and may include a P-type semiconductor layer doped with a first conductive dopant such as Ga, B, Mg, and the like. However, the disclosure is not limited thereto. The first semiconductor layer SCL1 may include various materials.

The active layer AL may be disposed between the first semiconductor layer SCL1 and the second semiconductor layer SCL2. The active layer AL may include a single-quantum well or multi-quantum well structure. A position of the active layer AL is not limited thereto and may vary depending on a type of the light emitting element LD.

A clad layer doped with a conductive dopant may be formed on a side and/or another side of the active layer AL. For example, the clad layer may include at least one of AlGaN and InAlGaN. However, the disclosure is not limited thereto.

The second semiconductor layer SCL2 may include a semiconductor of a second conductive type. The second semiconductor layer SCL2 may be disposed on the active layer AL and may include a type of semiconductor layer different from the first semiconductor layer SCL1. For example, the second semiconductor layer SCL2 may include an N-type semiconductor layer. For example, the second semiconductor layer SCL2 may include at least one of InAlGaN, GaN, AlGaN, InGaN, AlN, and InN, and may include a N-type semiconductor layer doped with a second conductive dopant such as Si, Ge, Sn, and the like. However, the disclosure is not limited thereto. The second semiconductor layer SCL2 may include various materials.

In case that a voltage higher than a threshold voltage is applied to the first end EP1 and the second end EP2 of the light emitting element LD, electron-hole pairs may recombine with each other in the active layer AL, and the light emitting element LD may emit light. By controlling light emitting of the light emitting element LD using this principle, the light emitting element LD may be used as a light source in various devices.

The insulating film INF may be disposed on a surface of the light emitting element LD. The insulating film INF may surround an outer surface of the active layer AL, and may further surround a portion of each of the first semiconductor layer SCL1 and the second semiconductor layer SCL2. The insulating film INF may have a single-layer or multi-layer structure.

The insulating film INF may expose the first end EP1 and the second end EP2 of the light emitting element LD having different polarities. For example, the insulating film INF may expose an end of each of the electrode layer ELL and the second semiconductor layer SCL2 adjacent to the first end EP1 and the second end EP2 of the light emitting element LD. The insulating film INF may secure electrical stability of the light emitting element LD. The insulating film INF may improve lifespan and efficiency by minimizing surface defects of the light emitting element LD. In case that multiple light emitting elements LD are disposed close to each other, the insulating film INF may prevent short circuit defects between the light emitting elements LD.

According to an embodiment, the insulating film INF may include at least one of silicon oxide (SiOₓ), silicon nitride (SiNₓ), silicon oxynitride (SiOₓN_{y}), aluminum oxide (AlₓO_{y}), and titanium oxide (TiOₓ). However, the disclosure is not limited thereto.

The electrode layer ELL may be disposed on the first semiconductor layer SCL1. The electrode layer ELL may be adjacent to the first end EP1. The electrode layer ELL may be electrically connected to the first semiconductor layer SCL1. A portion of the electrode layer ELL may be exposed. For example, the insulating film INF may expose a surface of the electrode layer ELL. The electrode layer ELL may be exposed in an area corresponding to the first end EP1. According to an embodiment, a side surface of the electrode layer ELL may be exposed. For example, the insulating film INF may cover the side surface of each of the first semiconductor layer SCL1, the active layer AL, and the second semiconductor layer SCL2, but may not cover at least a portion of the side surface of the electrode layer ELL, and electrical connection between other constituent elements and the electrode layer ELL adjacent to the first end EP1 may be readily established. According to an embodiment, the insulating film INF may expose not only the side surface of the electrode layer ELL but also a portion of the side surface of the first semiconductor layer SCL1 and/or the second semiconductor layer SCL2.

According to an embodiment, the electrode layer ELL may be an ohmic contact electrode. However, the disclosure is not limited thereto. For example, the electrode layer ELL may be a Schottky contact electrode.

According to an embodiment, the electrode layer ELL may include at least one of chromium (Cr), titanium (Ti), aluminum (Al), gold (Au), nickel (Ni), an oxide thereof, and an alloy thereof. However, the disclosure is not limited thereto. According to an embodiment, the electrode layer ELL may be substantially transparent. For example, the electrode layer ELL may include indium tin oxide (ITO). Accordingly, the electrode layer ELL may transmit the emitted light.

The structure and shape of the light emitting element LD are not limited to the embodiment described above, and the light emitting element LD may have various structures and shapes according to an embodiment. For example, the light emitting element LD may further include an additional electrode layer disposed on a surface of the second semiconductor layer SCL2 and adjacent to the second end EP2.

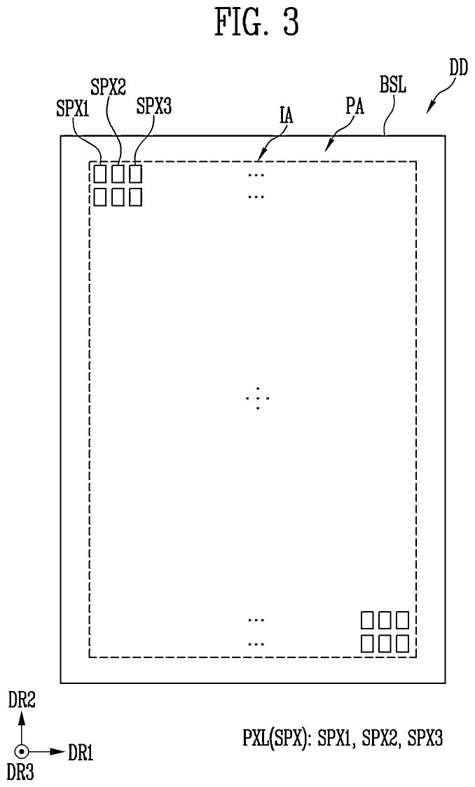

FIG. 3 is a schematic plan view illustrating a display device according to an embodiment.

Referring to FIG. 3, the display device DD may include a base layer BSL and a pixel PXL disposed on the base layer BSL. Although not shown in the drawing, the display device DD may further include a driving circuit unit (e.g., a scan driver and a data driver) for driving the pixel PXL, lines, and pads.

The display device DD (or base layer BSL) may include an internal area IA and a peripheral area PA. The peripheral area PA may be an area other than the internal area IA. The peripheral area PA may surround at least a portion of the internal area IA.

The base layer BSL may form a base surface of the display device DD. The base layer BSL may be a rigid or flexible substrate or film. For example, the base layer BSL may be a rigid substrate made of glass or tempered glass, a flexible substrate (or thin film) made of plastic or metal, or an insulating layer of at least one layer. The material and/or physical properties of the base layer BSL are not particularly limited. In embodiments, the base layer BSL may be substantially transparent. Here, “substantially transparent” may mean that light can be transmitted at a level of a transmittance or more. In another embodiment, the base layer BSL may be translucent or opaque. The base layer BSL may include a reflective material according to embodiments.

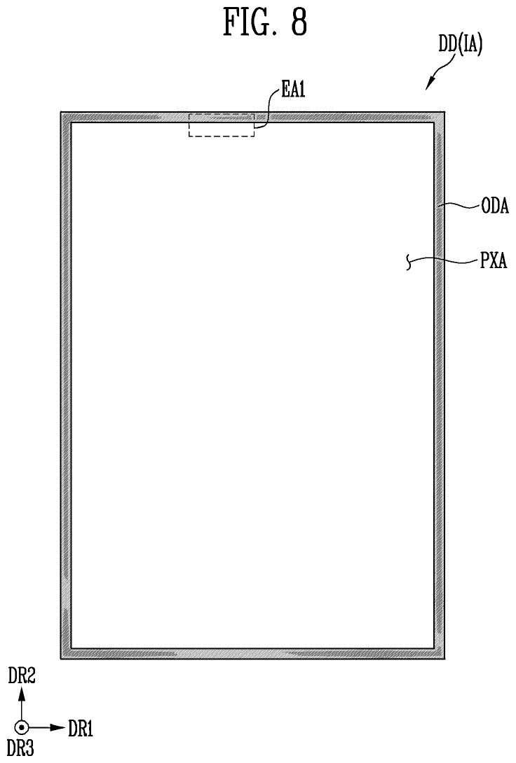

The internal area IA may include an area on which the pixel PXL is disposed (e.g., pixel area PXA (see FIG. 8)). The peripheral area PA may include an area in which the pixel PXL is not disposed (e.g., dead space). A driving circuit unit, lines, and pads connected to the pixel PXL of the internal area IA may be disposed in the peripheral area PA.

According to an embodiment, the pixel PXL (or sub-pixels SPX) may be arranged according to a stripe or PENTILE™ array structure, but the disclosure is not limited thereto, and the pixel PXL (or sub-pixels SPX) may be arranged in various patterns.

According to an embodiment, the pixel PXL (or sub-pixels SPX) may include a first sub-pixel SPX1, a second sub-pixel SPX2, and a third sub-pixel SPX3. Each of the first sub-pixel SPX1, the second sub-pixel SPX2, and the third sub-pixel SPX3 may be sub-pixels. At least one first sub-pixel SPX1, second sub-pixel SPX2, and third sub-pixel SPX3 may form one pixel unit configured to emit light of various colors.

For example, each of the first sub-pixel SPX1, the second sub-pixel SPX2, and the third sub-pixel SPX3 may emit light of a color. For example, the first sub-pixel SPX1 may be a red pixel that emits red light (e.g., first color), the second sub-pixel SPX2 may be a green pixel that emits green light (e.g., second color), and the third sub-pixel SPX3 may be a blue pixel that emits blue light (e.g., third color). According to an embodiment, the number of second sub-pixels SPX2 may be greater than the number of first and third sub-pixels SPX1 and SPX3. However, the color, type, and/or number of the first sub-pixel SPX1, the second sub-pixel SPX2, and the third sub-pixel SPX3 forming each pixel unit are not limited.

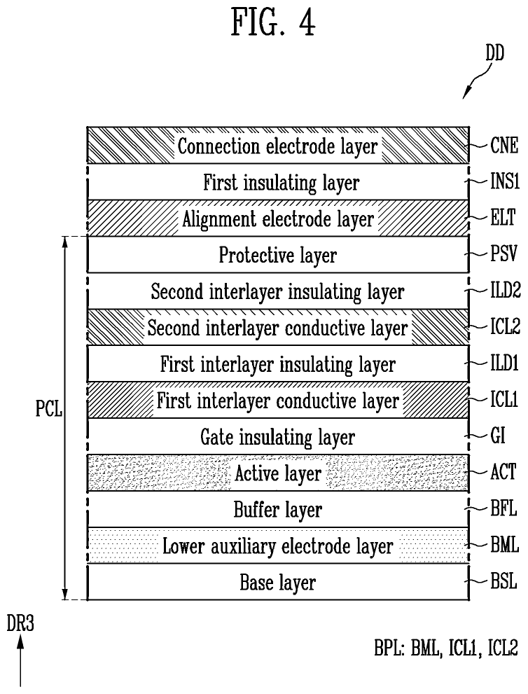

With reference to FIGS. 4 to 7, a cross-section and planar structure of the display device DD according to an embodiment will be described.

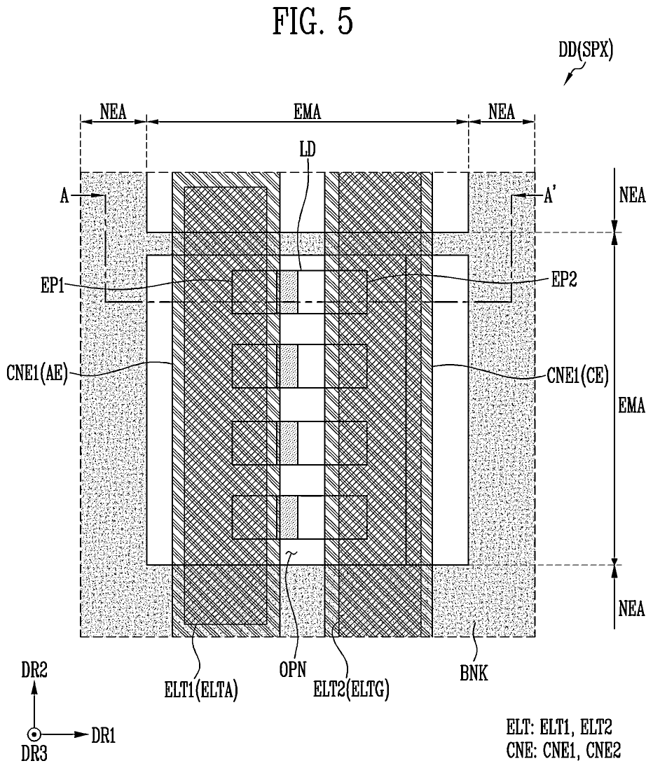

First, referring to FIG. 4, the stacked structure defined in the display device DD will be described. FIG. 4 is a schematic cross-sectional view illustrating a stacked structure of a display device according to an embodiment. In the drawings after FIG. 5, layers (e.g., patterned by the same process) that are the same as the layers described with reference to FIG. 4 may be expressed with the same hatching.

Referring to FIG. 4, the stacked structure included in the display device DD according to an embodiment may have a structure in which a base layer BSL, a lower auxiliary electrode layer BML, a buffer layer BFL, an active layer ACT, a gate insulating layer GI, a first interlayer conductive layer ICL1, a first interlayer insulating layer ILD1, a second interlayer conductive layer ICL2, a second interlayer insulating layer ILD2, a protective layer PSV, an alignment-electrode layer ELT, a first insulating layer INS1, and a connection-electrode layer CNE are sequentially stacked, and at least a portion thereof may be patterned.

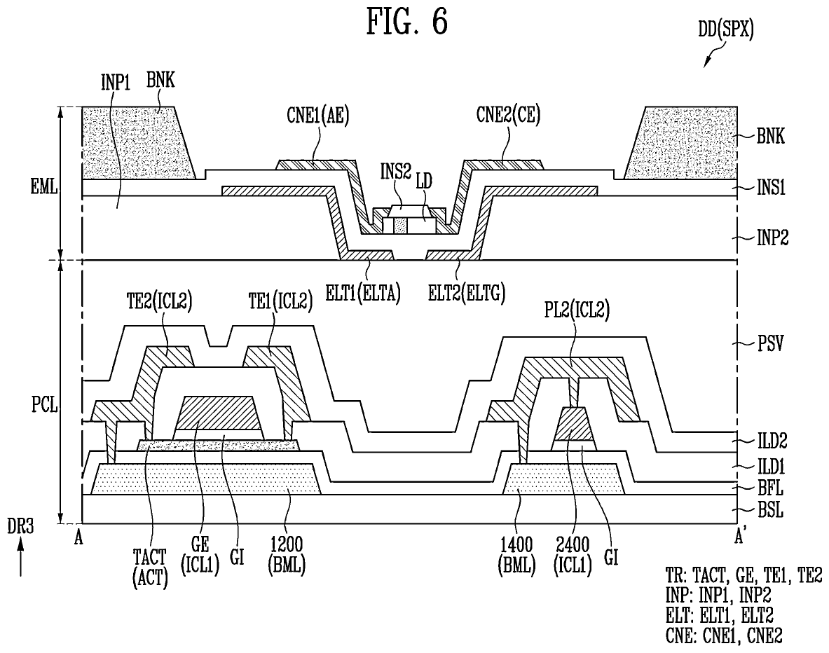

According to an embodiment, the lower auxiliary electrode layer BML, the buffer layer BFL, the active layer ACT, the gate insulating layer GI, the first interlayer conductive layer ICL1, the first interlayer insulating layer ILD1, the second interlayer conductive layer ICL2, the second interlayer insulating layer ILD2, and the protective layer PSV may form a pixel-circuit layer PCL (see FIG. 6) including pixel circuits.

According to an embodiment, the lower auxiliary electrode layer BML, the first interlayer conductive layer ICL1, and the second interlayer conductive layer ICL2 may form lower lines BPL. The lower lines BPL may be lines forming the pixel-circuit layer PCL and may include lines (e.g., wires or electrodes) formed lower than the alignment-electrode layer ELT.

The lower lines BPL according to an embodiment may further include additional conductive layers in addition to the lower auxiliary electrode layer BML, the first interlayer conductive layer ICL1, and the second interlayer conductive layer ICL2.

The base layer BSL may form (or configure) the base surface of the display device DD.

The buffer layer BFL may prevent impurities from diffusing into the active layer ACT or may prevent moisture permeation. According to an embodiment, the buffer layer BFL may include at least one of silicon nitride (SiNₓ), silicon oxide (SiOₓ), silicon oxynitride (SiOₓN_{y}), and aluminum oxide (AlₓO_{y}). However, the disclosure is not limited thereto.

The active layer ACT may include a semiconductor. For example, the active layer (ACT) may include at least one of polysilicon, low temperature polycrystalline silicon (LTPS), amorphous silicon, and an oxide semiconductor.

The lower auxiliary electrode layer BML, the first interlayer conductive layer ICL1, the second interlayer conductive layer ICL2, the alignment-electrode layer ELT, and the connection-electrode layer CNE may include a conductive material.

According to an embodiment, each of the lower auxiliary electrode layer BML, the first interlayer conductive layer ICL1, and the second interlayer conductive layer ICL2 may include one or more conductive layers. According to an embodiment, each of the lower auxiliary electrode layer BML, the first interlayer conductive layer ICL1, and the second interlayer conductive layer ICL2 may include at least one of gold (Au), silver (Ag), aluminum (Al), molybdenum (Mo), chromium (Cr), titanium (Ti), nickel (Ni), neodymium (Nd), copper (Cu), and platinum (Pt). According to an embodiment, the second interlayer conductive layer ICL2 may have a multi-layer structure in which titanium (Ti), copper (Cu), and indium tin oxide (ITO) are sequentially stacked. However, the disclosure is not limited thereto.

The gate insulating layer GI, the first interlayer insulating layer ILD1, the second interlayer insulating layer ILD2, the protective layer PSV, and the first insulating layer INS1 may be disposed between layers to electrically separate the active layer ACT, the first interlayer conductive layer (ICL1), the second interlayer conductive layer ICL2, the alignment-electrode layer ELT, and the connection-electrode layer CNE from each other. According to an embodiment, the above-described conductive layers may be electrically connected to each other using contact member(s) formed on at least one of the gate insulating layer GI, the first interlayer insulating layer ILD1, the second interlayer insulating layer ILD2, and the protective layer PSV.

According to an embodiment, the gate insulating layer GI, the first interlayer insulating layer ILD1, the second interlayer insulating layer ILD2, and the first insulating layer INS1 may include an inorganic material. For example, the inorganic material may include at least one of silicon nitride (SiNₓ), silicon oxide (SiOₓ), silicon oxynitride (SiOₓN_{y}), and aluminum oxide (AlₓO_{y}). According to an embodiment, the protective layer PSV may include an organic material. For example, organic materials may include at least one of an acrylic resin, an epoxy resin, a phenol resin, a polyamide resin, a polyimide resin, a polyester resin, a polyphenylenesulfide resin, and benzocyclobutene (BCB). However, the disclosure is not limited thereto.

According to an embodiment, the alignment-electrode layer ELT may include a conductive material. For example, the alignment-electrode layer ELT may include at least one of molybdenum (Mo), magnesium (Mg), silver (Ag), platinum (Pt), palladium (Pd), gold (Au), nickel (Ni), neodymium (Nd), iridium (Ir), chromium (Cr), titanium (Ti), copper (Cu), and aluminum (Al). However, the disclosure is not limited thereto.

According to an embodiment, the connection-electrode layer CNE may include a conductive material. The connection-electrode layer CNE may be electrically connected to the light emitting element LD. According to an embodiment, the connection-electrode layer CNE may include a transparent conductive material. For example, the connection-electrode layer CNE may include at least one of indium tin oxide (ITO), indium zinc oxide (IZO), and indium tin zinc oxide (ITZO). However, the disclosure is not limited thereto. The first insulating layer INS1 may be disposed between the alignment-electrode layer ELT and the connection-electrode layer CNE.

With reference to FIGS. 5 to 7, a schematic planar and cross-sectional structure of the display device DD according to an embodiment will be described.

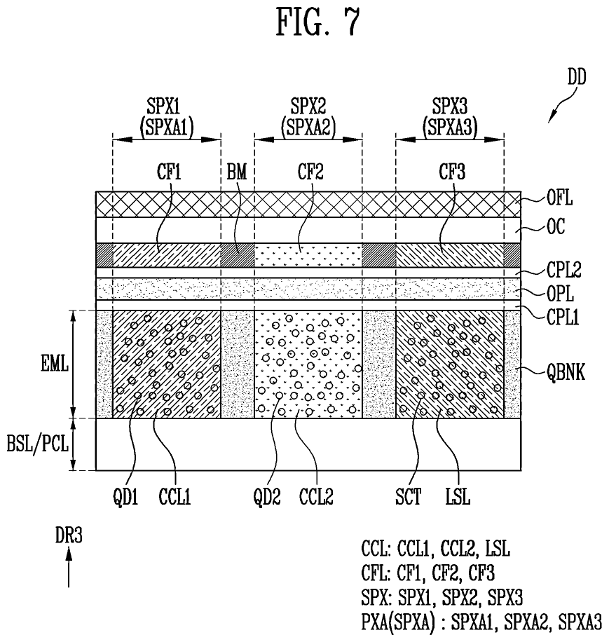

FIGS. 5 and 6 are schematic drawings illustrating a display device according to an embodiment. FIG. 5 is a schematic plan view illustrating a display device DD according to an embodiment. FIG. 6 is a schematic cross-sectional view taken along line A-A′ of FIG. 5. FIG. 7 is a schematic cross-sectional view illustrating a display device according to an embodiment.

The display device DD may include a light emitting area EMA and a non-light emitting area NEA. The display device DD may include a bank BNK, an alignment-electrode layer ELT, a light emitting element LD, and a connection-electrode layer CNE.

In a plan view, the light emitting area EMA may overlap the opening OPN defined by the bank BNK. The light emitting elements LD may be disposed in the light emitting area EMA. The light emitting elements LD may not be disposed in the non-light emitting area NEA.

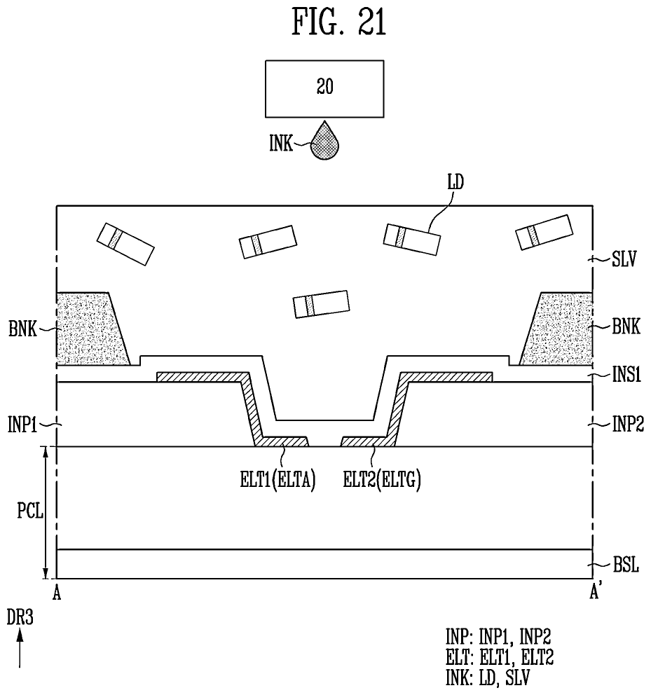

The bank BNK may form (or include) an opening OPN. For example, the bank BNK may have a shape that protrudes in the thickness direction (e.g., third direction DR3) of the base layer BSL and may surround an area in a plan view. According to an embodiment, the ink INK (sec FIG. 21) including the light emitting element LD may be supplied to the opening OPN defined by the bank BNK, so that the light emitting element LD may be disposed in the opening OPN.

According to an embodiment, the bank BNK may include an organic material such as an acrylic resin, an epoxy resin, a phenol resin, a polyamide resin, a polyimide resin, a polyester resin, a polyphenylenesulfide resin, or benzocyclobutene (BCB). However, the disclosure is not limited thereto.

The alignment-electrode layer ELT may include electrodes for aligning the light emitting element LD. According to an embodiment, the alignment-electrode layer ELT may include a first electrode ELT1 and a second electrode ELT2. According to an embodiment, the first electrode ELT1 may be the first alignment electrode ELTA, and the second electrode ELT2 may be the second alignment electrode ELTG.

The light emitting element LD may be disposed (or aligned) on the alignment-electrode layer ELT. According to an embodiment, the light emitting element LD may be aligned between the first electrode ELT1 and the second electrode ELT2 in a plan view. The light emitting elements LD may form (or configure) a light emitting unit.

According to an embodiment, the first electrode ELT1 and the second electrode ELT2 may be spaced apart from each other in the first direction DR1 in the light emitting area EMA.

According to an embodiment, the first electrode ELT1, which is the first alignment electrode ELTA, may be an electrode to which an alternating current signal can be supplied to align the light emitting elements LD. The first electrode ELT1 may be an electrode to which an anode signal can be supplied so that the light emitting elements LD emit light. The second electrode ELT2, which is the second alignment electrode ELTG, may be an electrode to which a ground signal can be supplied to align the light emitting elements LD. The second electrode ELT2 may be an electrode to which a cathode signal can be supplied so that the light emitting elements LD emit light.

The first electrode ELT1 (or first alignment electrode ELTA) and the second electrode ELT2 (or second alignment electrode ELTG) may be supplied (or provided) with a first alignment signal and a second alignment signal in a process step in which the light emitting elements LD are aligned, respectively. For example, the ink INK including the light emitting element LD may be supplied (or provided) to the opening OPN, the first alignment signal may be supplied to the first electrode ELT1, and the second alignment signal may be supplied to the second electrode ELT2. The first alignment signal and the second alignment signal may have different waveforms, potentials, and/or phases. For example, the first alignment signal may be an alternating current signal and the second alignment signal may be a ground signal. However, the disclosure is not limited to the examples described above. An electric field may be formed between (or on) the first electrode ELT1 and the second electrode ELT2, and the light emitting elements LD may be aligned between the first electrode ELT1 and the second electrode ELT2 based on the electric field. For example, the light emitting elements LD may be moved (or rotated) by a force (e.g., dielectrophoresis (DEP) force) due to the electric field and may be aligned (or disposed) on the first alignment electrode ELTA and the second alignment electrode ELTG.

The light emitting element LD may emit light based on a provided electrical signal. For example, the light emitting element LD may provide light based on a first electrical signal (e.g., anode signal) provided from the first connection electrode CNE1 and a second electrical signal (e.g., cathode signal) provided from the second connection electrode CNE2.

The first end EP1 of the light emitting element LD may be disposed adjacent to the first electrode ELT1, and the second end EP2 of the light emitting element LD may be disposed adjacent to the second electrode ELT2.

The light emitting element LD may be disposed in the opening OPN. The light emitting element LD may form a light emitting area. The light emitting area may include an area in which the light emitting element LD is disposed.

The connection-electrode layer CNE may be disposed on the first and second ends EP1 and EP2 of the light emitting elements LD. The first connection electrode CNE1 may be disposed on the first ends EP1 and electrically connected to the first ends EP1 of the light emitting elements LD. The second connection electrode CNE2 may be disposed on the second ends EP2 and electrically connected to the second ends EP2 of the light emitting elements LD.

According to an embodiment, the connection-electrode layer CNE may include a first connection electrode CNE1 and a second connection electrode CNE2. The first connection electrode CNE1 may be an anode connection electrode AE, and the second connection electrode CNE2 may be a cathode connection electrode CE.

FIG. 6 schematically illustrates the cross-sectional structure of the display device DD focusing on the pixel-circuit layer PCL where the pixel circuit is formed and the light emitting element layer EML where the light emitting elements LD are disposed.

Referring to FIG. 6, the display device DD may include the pixel-circuit layer PCL and the light emitting element layer EML. For convenience of description, FIG. 6 is illustrated focusing on a driving transistor TR among the circuit elements forming the pixel circuit.

The base layer BSL may provide an area where the pixel-circuit layer PCL and the light emitting element layer EML are disposed.

The pixel-circuit layer PCL may be disposed on the base layer BSL. The pixel-circuit layer PCL may include the layers described above with reference to FIG. 4. For example, the pixel-circuit layer PCL may include a first lower auxiliary electrode layer 1200, a second lower auxiliary electrode layer 1400, a driving transistor TR, and a second power line PL2.

The first lower auxiliary electrode layer 1200 and the second lower auxiliary electrode layer 1400 may be formed by the lower auxiliary electrode layer BML. The first lower auxiliary electrode layer 1200 may be electrically connected to the second transistor electrode TE2 of the driving transistor TR, and may overlap the driving active layer TACT of the driving transistor TR in a plan view. The second lower auxiliary electrode layer 1400 may be electrically connected to the second power line PL2.

The buffer layer BFL may be disposed on the base layer BSL. The buffer layer BFL may cover the lower auxiliary electrode layer BML.

The driving transistor TR may be a thin film transistor. The driving transistor TR may be electrically connected to the light emitting element LD. According to an embodiment, the driving transistor TR may include a driving active layer TACT, a first transistor electrode TE1, a second transistor electrode TE2, and a gate electrode GE.

The driving active layer TACT may be formed by the active layer ACT and may include a first contact region contacting the first transistor electrode TE1 and a second contact region contacting the second transistor electrode TE2. According to an embodiment, the driving active layer TACT may be a driving active layer. One of the first transistor electrode TE1 and the second transistor electrode TE2 may be a source electrode, and another one of the first transistor electrode TE1 and the second transistor electrode TE2 may be a drain electrode.

The gate electrode GE may be disposed on the gate insulating layer GI. A position of the gate electrode GE may correspond to a position of a channel region of the driving active layer TACT.

The gate insulating layer GI may be disposed on the buffer layer BFL. The gate insulating layer GI may cover the driving active layer TACT.

The first interlayer insulating layer ILD1 may be disposed on the gate insulating layer GI. The first interlayer insulating layer ILD1 may cover the gate electrode GE and the conductive layer 2400. The conductive layer 2400 may be formed of the first interlayer conductive layer ICL1 and may be electrically connected to the second power line PL2.

The first transistor electrode TE1 and the second transistor electrode TE2 may be disposed on the first interlayer insulating layer ILD1. The second transistor electrode TE2 may be electrically connected to the first power line PL1. The first transistor electrode TE1 may be electrically connected to the first electrode ELT1 through a first contact member penetrating the second interlayer insulating film ILD2 and the protective layer PSV.

The second power line PL2 may be disposed on the first interlayer insulating layer ILD1. The second power line PL2 may be electrically connected to the second lower auxiliary electrode layer 1400 and may be electrically connected to the second electrode ELT2 through a second contact member penetrating the second interlayer insulating film ILD2 and the protective layer PSV.

The second interlayer insulating layer ILD2 may be disposed on the first interlayer insulating layer ILD1. The second interlayer insulating layer ILD2 may cover the first transistor electrode TE1, the second transistor electrode TE2, and the second power line PL2.

The protective layer PSV may be disposed on the second interlayer insulating layer ILD2. According to an embodiment, the protective layer PSV may be a via layer.

The light emitting element layer EML may be disposed on the pixel-circuit layer PCL. The light emitting element layer EML may include insulating patterns INP, an alignment-electrode layer ELT, a first insulating layer INS1, a bank BNK, a light emitting element LD, a second insulating layer INS2, and a connection-electrode layer CNE.

The insulating patterns INP may include first and second insulating patterns INP1 and INP2. The first and second insulating patterns INP1 and INP2 may be disposed on the protective layer PSV. The first and second insulating patterns INP1 and INP2 may have various shapes according to an embodiment. In an embodiment, the first and second insulating patterns INP1 and INP2 may protrude in the thickness direction (e.g., third direction DR3) of the base layer BSL.

The first and second insulating patterns INP1 and INP2 may form a step so that the light emitting elements LD can be readily aligned in the light emitting area EMA. According to an embodiment, the first and second insulating patterns INP1 and INP2 may be partition walls. According to an embodiment, the first and second insulating patterns INP1 and INP2 may include at least one organic material and/or an inorganic material. However, the disclosure is not limited thereto.

The alignment-electrode layer ELT may be disposed on the protective layer PSV and/or the first and second insulating patterns INP1 and INP2. The first electrode ELT1 may receive a first alignment signal and/or a first power through the first contact member. The second electrode ELT2 may receive a second alignment signal and/or a second power through the second contact member.

The first insulating layer INS1 may be disposed on the alignment-electrode layer ELT. For example, the first insulating layer INS1 may cover the first electrode ELT1 and the second electrode ELT2.

The bank BNK may be disposed on the first insulating layer INS1. As described above, the bank BNK may form a space in which the ink INK including the light emitting element LD can be accommodated.

The light emitting element LD may be disposed on the first insulating layer INS1 in the area surrounded by the bank BNK. According to an embodiment, the light emitting element LD may emit light based on electrical signals (e.g., anode signal and cathode signal) provided from the first connection electrode CNE1 and the second connection electrode CNE2.

The second insulating layer INS2 may be disposed on the light emitting element LD. The second insulating layer INS2 may cover the active layer AL of the light emitting element LD. The second insulating layer INS2 may expose at least a portion of the light emitting element LD. For example, the second insulating layer INS2 may not cover the first end EP1 and the second end EP2 of the light emitting element LD, and accordingly, the first end EP1 and EP2 of the light emitting element LD may be exposed and electrically connected to the first connection electrode CNE1 and the second connection electrode CNE2, respectively. According to an embodiment, another portion of the second insulating layer INS2 may be disposed on the bank BNK and the first insulating layer INS1.

In case that the second insulating layer INS2 is formed on the light emitting elements LD after the alignment of the light emitting elements LD is completed, the light emitting elements LD may be prevented from leaving an aligned position.

The second insulating layer INS2 may have a single-layer or multi-layer structure. The second insulating layer INS2 may include at least one of silicon oxide (SiNₓ), silicon oxide (SiOₓ), silicon oxynitride (SiOₓN_{y}), aluminum nitride (AlNₓ), aluminum oxide (AlₓO_{y}), zirconium oxide (ZrOₓ), hafnium oxide (HfOₓ), and titanium oxide (TiOₓ). However, the disclosure is not limited thereto.

The first connection electrode CNE1 and the second connection electrode CNE2 may be disposed on the first insulating layer INS1 and the second insulating layer INS2. The first connection electrode CNE1 may be electrically connected to the first end EP1 of the light emitting element LD. The second connection electrode CNE2 may be electrically connected to the second end EP2 of the light emitting element LD.

The first connection electrode CNE1 may be electrically connected to the first electrode ELT1 through a first contact portion penetrating the first insulating layer INS1, and the second connection electrode CNE2 may be electrically connected to the second electrode ELT2 through a second contact portion penetrating the first insulating layer INS1. According to an embodiment, the first connection electrode CNE1 may be directly (or electrically) connected to a line of the pixel-circuit layer PCL through the first contact portion. The second connection electrode CNE2 may be directly (or electrically) connected to a line of the pixel-circuit layer PCL through a second contact portion.

According to an embodiment, the first connection electrode CNE1 and the second connection electrode CNE2 may be patterned at the same time in the same process. However, the disclosure is not limited thereto. After one of the first connection electrode CNE and the second connection electrode CNE2 is patterned, another one of the first connection electrode CNE1 and the second connection electrode CNE2 may be patterned.

FIG. 7 schematically illustrates the cross-sectional structure of the display device DD focusing on constituent elements disposed on the light emitting element layer EML.

Referring to FIG. 7, sub-pixel areas SPXA, respectively, corresponding to the sub-pixels SPX may be formed in the display area DA. According to an embodiment, the sub-pixel areas SPXA may be included in the pixel area PXA. The sub-pixel areas SPXA may include a first sub-pixel area SPXA1 corresponding to the first sub-pixel SPX1, a second sub-pixel area SPXA2 corresponding to the second sub-pixel SPX2, and a third sub-pixel area SPXA3 corresponding to the third sub-pixel SPX3. The first sub-pixel area SPXA1, the second sub-pixel area SPXA2, and the third sub-pixel area SPXA3 may be arranged in the first direction DR1.

An additional bank QBNK may be disposed between or at the boundary of the first to third sub-pixel areas SPXA1, SPXA2, and SPXA3, and may define a space (or area) overlapping each of the first to third sub-pixel areas SPXA1, SPXA2, and SPXA3. The space defined by the additional bank QBNK may be an area where a color conversion layer CCL can be provided.

The additional bank QBNK may be disposed to surround an area in the light emitting element layer EML in a plan view. The additional bank QBNK may protrude in the thickness direction (e.g., third direction DR3) of the base layer BSL, so that the additional bank QBNK may define an area, and a space where the conversion layer CCL is provided may be formed in the area.

The additional banks QBNK may include an organic material. For example, the additional banks QBNK may include at least one of an acrylic resin, an epoxy resin, a phenol resin, a polyamide resin, a polyimide resin, a polyester resin, a polyphenylenesulfide resin, and benzocyclobutene (BCB). However, the disclosure is not limited thereto.

The color conversion layer CCL may be disposed on the light emitting elements LD in a space surrounded by the additional bank QBNK. The color conversion layer CCL may include a first color conversion layer CCL1 disposed in the first sub-pixel SPX1, a second color conversion layer CCL2 disposed in the second sub-pixel SPX2, and a scattering layer LSL disposed in the third sub-pixel SPX3.

The color conversion layer CCL may be disposed on the light emitting element LD. The color conversion layer CCL may be configured to change the wavelength of light. According to an embodiment, the first to third sub-pixels SPX1, SPX2, and SPX3 may include light emitting elements LD that emit light of the same color. For example, the first to third sub-pixels SPX1, SPX2, and SPX3 may include light emitting elements LD that emit light of a third color (or blue color). The color conversion layer CCL including color conversion particles may be disposed on the first to third sub-pixels SPX1, SPX2, and SPX3, so that a full-color image can be displayed.

The first color conversion layer CCL1 may include first color conversion particles that convert the third color light emitted from the light emitting element LD into the first color light. For example, the first color conversion layer CCL1 may include multiple first quantum dots QD1 dispersed in a matrix material such as a base resin.

According to an embodiment, in case that the light emitting element LD is a blue light emitting element that emits blue light and the first sub-pixel SPX1 is a red pixel, the first color conversion layer CCL1 may include the first quantum dot QD1 that converts blue light emitted from blue light emitting element into red light. The first quantum dot QD1 may absorb blue light to shift a wavelength according to an energy transition, thereby emitting red light. In case that the first sub-pixel SPX1 is a pixel of another color, the first color conversion layer CCL1 may include the first quantum dot QD1 corresponding to the color of the first sub-pixel SPX1.

The second color conversion layer CCL2 may include second color conversion particles that convert the third color light emitted from the light emitting element LD into the second color light. For example, the second color conversion layer CCL2 may include multiple second quantum dots QD2 dispersed in a matrix material such as a base resin.

According to an embodiment, in case that the light emitting element LD is a blue light emitting element that emits blue light and the second sub-pixel SPX2 is a green pixel, the second color conversion layer CCL2 may include the second quantum dot QD2 that converts blue light emitted from the blue light emitting element into green light. The second quantum dot QD2 may absorb blue light to shift a wavelength according to an energy transition, thereby emitting green light. In case that the second sub-pixel SPX2 is a pixel of another color, the second color conversion layer CCL2 may include the second quantum dot QD2 corresponding to the color of the second sub-pixel SPX2.

According to an embodiment, blue light having a relatively short wavelength in a visible light range may be incident on the first quantum dot QD1 and the second quantum dot QD2, so that the absorption coefficient of the first quantum dot QD1 and the second quantum dot QD2 can be increased. Accordingly, the light efficiency of light emitted from the first sub-pixel SPX1 and the second sub-pixel SPX2 may be improved, and excellent color reproducibility may be secured. The light emitting unit of the first to third sub-pixels SPX1, SPX2, and SPX3 may be composed of the light emitting elements LD (e.g., blue light emitting elements) of the same color, thereby the manufacturing efficiency of the display device can be increased.

The scattering layer LSL may be provided to efficiently use the third color (or blue) light emitted from the light emitting element LD. For example, in case that the light emitting element LD is a blue light emitting element that emits blue light and the third sub-pixel SPX3 is a blue pixel, the scattering layer LSL may include at least one type of scattering material SCT to use efficiently the light emitted from the light emitting element LD. For example, the scattering material SCT of the scattering layer LSL may include various light scattering particles or light scattering materials. For example, the scattering material SCT may include at least one of silica (SiOₓ) (e.g., silica beads, hollow silica, etc.), titanium oxide (TiOₓ), zirconium oxide (ZrOₓ), aluminum oxide (AlₓO_{y}), indium oxide (InₓO_{y}), zinc oxide (ZnOₓ), tin oxide (SnOₓ), and antimony oxide (SbₓO_{y}). However, the disclosure is not limited thereto. The scattering material SCT may be not disposed only in the third sub-pixel SPX3 and may be included in the first color conversion layer CCL1 or the second color conversion layer CCL2. According to an embodiment, the scattering layer LSL including a transparent polymer may be provided by omitting the scattering material SCT.

A first capping layer CPL1 may be disposed on the color conversion layer CCL. The first capping layer CPL1 may be provided over the first to third sub-pixels SPX1, SPX2, and SPX3. The first capping layer CPL1 may cover the color conversion layer CCL. The first capping layer CPL1 may prevent impurities such as moisture or air from penetrating from the outside and damaging or contaminating the color conversion layer CCL.

The first capping layer CPL1 may be an inorganic layer and may include at least one of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}).

An optical layer OPL may be disposed on the first capping layer CPL1. The optical layer OPL may serve to improve light extraction efficiency by recycling light provided from the color conversion layer CCL through total reflection. To this end, the optical layer OPL may have a relatively low refractive index than a refractive index of the color conversion layer CCL.

A second capping layer CPL2 may be disposed on the optical layer OPL. The second capping layer CPL2 may be provided over the first to third sub-pixels SPX1, SPX2, and SPX3. The second capping layer CPL2 may cover the optical layer OPL. The second capping layer CPL2 may prevent impurities such as moisture or air from penetrating from the outside and damaging or contaminating the optical layer OPL.

The second capping layer CPL2 may be an inorganic layer and may include at least one of silicon nitride (SiNₓ), aluminum nitride (AlNₓ), titanium nitride (TiNₓ), silicon oxide (SiOₓ), aluminum oxide (AlₓO_{y}), titanium oxide (TiOₓ), silicon oxycarbide (SiOₓC_{y}), and silicon oxynitride (SiOₓN_{y}).

A color filter layer CFL may be disposed on the second capping layer CPL2. The color filter layer CFL may include color filters CF1, CF2, and CF3 that match the color of each pixel PXL. A full-color image may be displayed by disposing color filters CF1, CF2, and CF3 matching the color of each of the first to third sub-pixels SPX1, SPX2, and SPX3.

The color filter layer CFL may include a first color filter CFI that is disposed in the first sub-pixel SPX1 and selectively transmits light emitted from the first sub-pixel SPX1, a second color filter CF2 that is disposed in the second sub-pixel SPX2 and selectively transmits light emitted from the second sub-pixel SPX2, and a third color filter CF3 that is disposed in the third sub-pixel SPX3 and selectively transmits light emitted from the third sub-pixel SPX3.

According to an embodiment, the first color filter CF1, the second color filter CF2, and the third color filter CF3 may be a red color filter, a green color filter, and a blue color filter, respectively, but are not limited thereto. Hereinafter, the term “color filter CF” or “color filters CF” may refer to any color filter of the first color filter CF1, the second color filter CF2, and the third color filter CF3, or may refer to two or more types of color filters collectively.

The first color filter CFI may overlap the first color conversion layer CCL1 in the thickness direction (e.g., third direction DR3) of the base layer BSL. The first color filter CF1 may include a color filter material that selectively transmits light of the first color (or red). For example, in case that the first sub-pixel SPX1 is a red pixel, the first color filter CFI may include a red color filter material.

The second color filter CF2 may overlap the second color conversion layer CCL2 in the thickness direction (e.g., third direction DR3) of the base layer BSL. The second color filter CF2 may include a color filter material that selectively transmits light of the second color (or green). For example, in case that the second sub-pixel SPX2 is a green pixel, the second color filter CF2 may include a green color filter material.

The third color filter CF3 may overlap the scattering layer LSL in the thickness direction (e.g., third direction DR3) of the base layer BSL. The third color filter CF3 may include a color filter material that selectively transmits third color (or blue) light. For example, in case that the third sub-pixel SPX3 is a blue pixel, the third color filter CF3 may include a blue color filter material.

According to an embodiment, a light blocking layer BM may be further disposed between the first to third color filters CF1, CF2, and CF3. Accordingly, in case that the light blocking layer BM is formed between the first to third color filters CF1, CF2, and CF3, color mixing defects visible from the front surface or side surface of the display device DD may be prevented. The material of the light blocking layer BM may be not particularly limited and may include various light absorbing materials. For example, the light blocking layer BM may include a black matrix or may be implemented by stacking the first to third color filters CF1, CF2, and CF3.

An overcoat layer OC may be disposed on the color filter layer CFL. The overcoat layer OC may be provided over the first to third sub-pixels SPX1, SPX2, and SPX3. The overcoat layer OC may cover the lower member including the color filter layer CFL. The overcoat layer OC may prevent moisture or air from penetrating into the above-described lower member. The overcoat layer OC may protect the above-described lower member from foreign substances such as dust.

The overcoat layer OC may include an organic material, such as an acrylic resin, an epoxy resin, a phenol resin, a polyamide resin, a polyimide resin, a polyester resin, a polyphenylenesulfide resin, or benzocyclobutene. However, the disclosure is not limited thereto, and the overcoat layer OC may include an inorganic material such as silicon oxide (SiOₓ), silicon nitride (SiNₓ), silicon oxynitride (SiOₓN_{y}), aluminum nitride (AlNₓ), aluminum oxide (AlₓO_{y}), zirconium oxide (ZrOₓ), hafnium oxide (HfOₓ), or titanium oxide (TiOₓ).

The outer film layer OFL may be disposed on the overcoat layer OC. The outer film layer OFL may be disposed at an outer side of the display device DD to reduce external influences. The outer film layer OFL may be provided over the first to third sub-pixels SPX1, SPX2, and SPX3. According to an embodiment, the outer film layer OFL may include at least one of a polyethyleneterephthalate (PET) film, a low-reflection film, a polarizing film, and a transmittance controllable film, but the disclosure is not limited thereto. According to an embodiment, the pixel PXL may include an upper substrate instead of the outer film layer OFL.

With reference to FIGS. 8 to 17, a display device DD including an outer-dam area ODA according to an embodiment will be described. For convenience of description, duplicate description is briefly explained or not repeated.

A display device DD including an outer-dam area ODA according to an embodiment will be described with reference to FIGS. 8 to 10.

FIGS. 8 to 10 are schematic drawings illustrating a display device including an outer-dam area according to an embodiment.

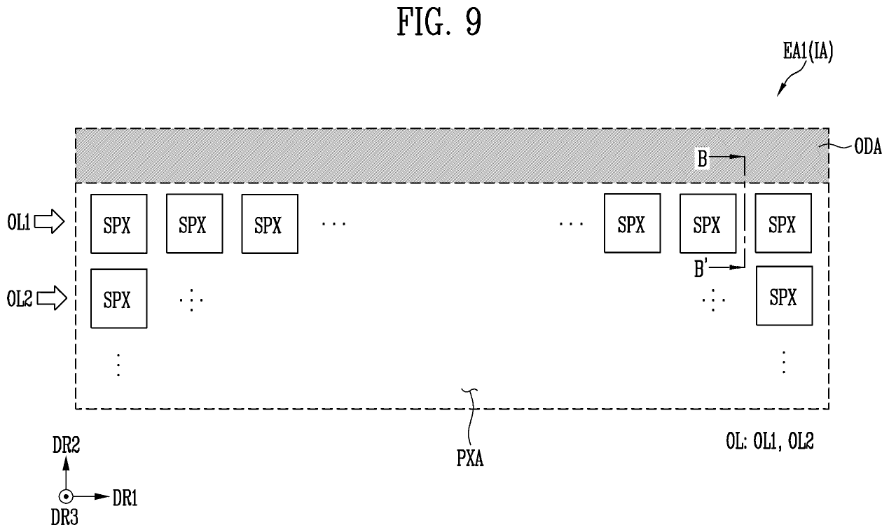

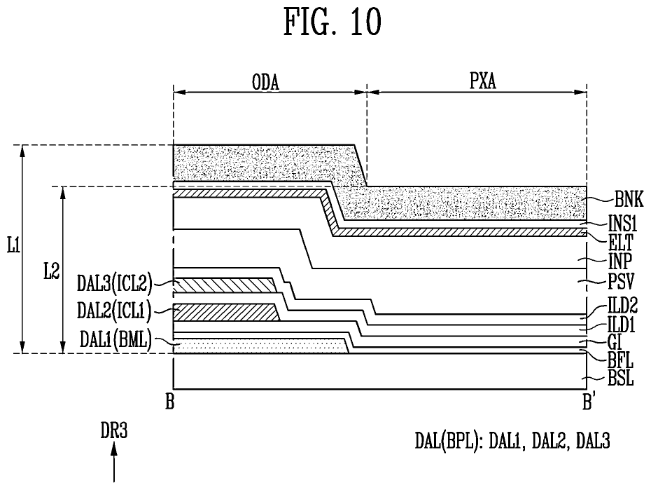

FIG. 8 is a schematic plan view illustrating a display device including an outer-dam area according to an embodiment. FIG. 9 is a schematic enlarged view of EA1 area of FIG. 8. FIG. 10 is a schematic cross-sectional view taken along line B-B′ of FIG. 9.

The display device DD according to an embodiment may include a pixel area PXA and an outer-dam area ODA.

The pixel area PXA may be an area where the sub-pixel SPX is disposed. The pixel area PXA may include a display area where an image is displayed.

The outer-dam area ODA may surround at least a portion of the pixel area PXA. The outer-dam area ODA may be formed at a periphery of the pixel area PXA. According to an embodiment, the outer-dam area ODA may be formed at the edge of the pixel area PXA.

According to an embodiment, the outer-dam area ODA may entirely surround the pixel area PXA in a plan view. The outer-dam area ODA may surround all edges of the pixel area PXA. The outer-dam area ODA may form a closed-loop in which the pixel area PXA can be disposed.

However, the disclosure is not limited thereto, and according to an embodiment, the outer-dam area ODA may not be disposed at a portion of the edges of the pixel area PXA and may form an open-loop in which the pixel area PXA can be disposed.

According to an embodiment, the outer-dam area ODA may be adjacent to the sub-pixels SPX. For example, the outer-dam area ODA may be directly adjacent to the sub-pixels SPX disposed at the outermost edge of the pixel area PXA.

The sub-pixels SPX may be disposed along each of the outer lines OL. The outer lines OL may be pixel row lines or pixel column lines adjacent to the edge of the internal area IA. For convenience of description, drawings after FIG. 9 will be described based on an embodiment in which the outer lines OL are pixel row lines.

The outer lines OL may include a first outer line OL1 and a second outer line OL2. The first outer line OL1 may be the outermost line among the outer lines OL. The first outer line OL1 may be disposed between the outer-dam area ODA and the second outer line OL2.

The sub-pixels SPX may include sub-pixels SPX disposed on the first outer line OL1. The sub-pixels SPX may include sub-pixels SPX disposed on the second outer line OL2.

A protruding structure that protrudes more than a structure formed in the pixel area PXA may be formed in the outer-dam area ODA.

According to an embodiment, the protruding structure formed in the outer-dam area ODA may be formed by stacking at least a portion of the lower lines BPL in the thickness direction (e.g., third direction DR3) of the base layer BSL. For example, at least a portion of the lower lines BPL may be stacked and form a dam formation line DAL.

The dam formation line DAL may be formed by the lower lines BPL. The dam formation line DAL may include two or more of the lower lines BPL. According to an embodiment, the dam formation line DAL may include all lower lines BPL.

According to an embodiment, the dam formation line DAL may include multiple conductive layers. The dam formation line DAL may include a first dam formation line DAL1, a second dam formation line DAL2, and a third dam formation line DAL3. The first dam formation line DAL1 may be formed by the lower auxiliary electrode layer BML. The second dam formation line DAL2 may be formed by the first interlayer conductive layer ICL1. The third dam formation line DAL3 may be formed by the second interlayer conductive layer ICL2.

According to an embodiment, as the dam formation lines DAL are formed by the lower lines BPL, the protruding structure may be formed on the periphery of the pixel area PXA without adding a separate process, so the process step may be simplified, and process costs may be reduced.

Although not shown in the drawing, in case that the lower lines BPL further include additional conductive layer(s) in addition to the lower auxiliary electrode layer BML, the first interlayer conductive layer ICL1, and the second interlayer conductive layer ICL2, the dam formation line DAL may further include an n-th dam formation line (here, n is an integer of 3 or more) that is a layer formed by additional conductive layer(s).

According to the embodiment, as the dam formation line DAL is disposed in the outer-dam area ODA, the uppermost part of the bank BNK in the outer-dam area ODA may be formed higher than the uppermost portion of the bank BNK in the pixel area PXA.

For example, in the outer-dam area ODA, the upper surface of the bank BNK may be spaced apart from the base layer BSL by a first distance L1. In an area (e.g., pixel area PXA) other than the outer-dam area ODA, the upper surface of the bank BNK may be spaced apart from the base layer BSL by a second distance L2. The first distance L1 may be greater than the second distance L2.

The protruding structure may be defined in the outer-dam area ODA, and as described above, the movement (e.g., flow) of the solvent SLV may be restricted to the interior of the outer-dam area ODA.

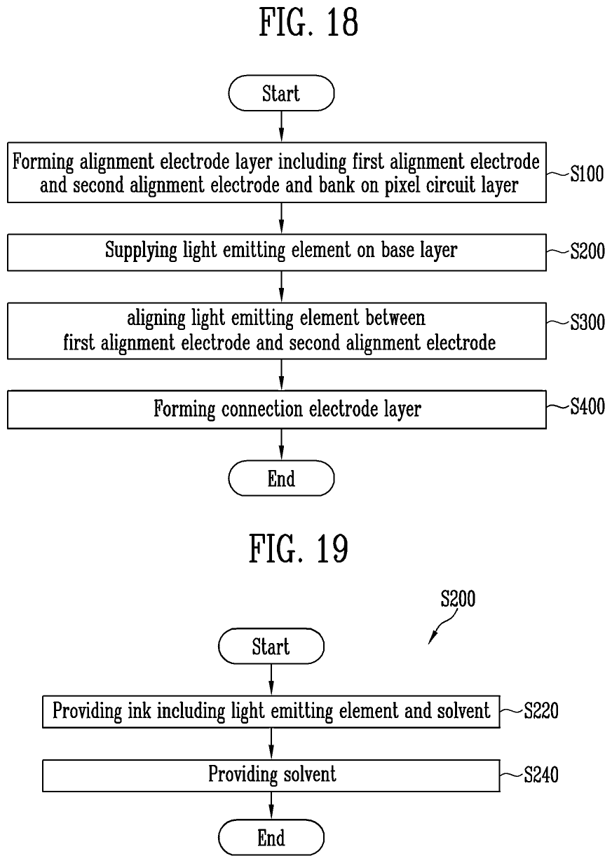

As the outer-dam area ODA for defining the movement of the solvent SLV is defined, the convenience of the process for supplying the light emitting element LD into the pixel area PXA may be improved. Detailed information regarding this will be described below with reference to the drawings after FIG. 18.

According to an embodiment, the outer-dam area ODA may entirely surround the pixel area PXA in a plan view, creating a defined space configured to accommodate fluid.

For example, the solvent SLV may be supplied on the pixel-circuit layer PCL (e.g., base layer BSL). According to an embodiment, the outer-dam area ODA may form an area in which the solvent SLV is accommodated. The outer-dam area ODA may restrict an area over which the solvent SLV flows.

For example, the outer-dam area ODA may be formed at the periphery of the pixel area PXA to form a loop structure surrounding the pixel area PXA, and a range in which the solvent SLV flow may be restricted by the outer-dam area ODA. Accordingly, the range in which the solvent SLV can flow may be determined to correspond to (e.g., to be substantially equal to) the area in which the pixel area PXA is to be formed.

The sub-pixel SPX may not be formed in the outer-dam area ODA. For example, the light emitting element LD may not be disposed in the outer-dam area ODA.

For example, in order to supply the light emitting element LD on the pixel-circuit layer PCL (e.g., base layer BSL), the light emitting element LD may be approximately supplied to the area in which the pixel area PXA is to be formed, and as more solvent SLV is supplied in the subsequent process, the light emitting element LD may be moved throughout the pixel area PXA. Accordingly, the light emitting element LD may be disposed throughout the pixel area PXA, but the light emitting element LD may not be disposed in the outer dam area ODA.

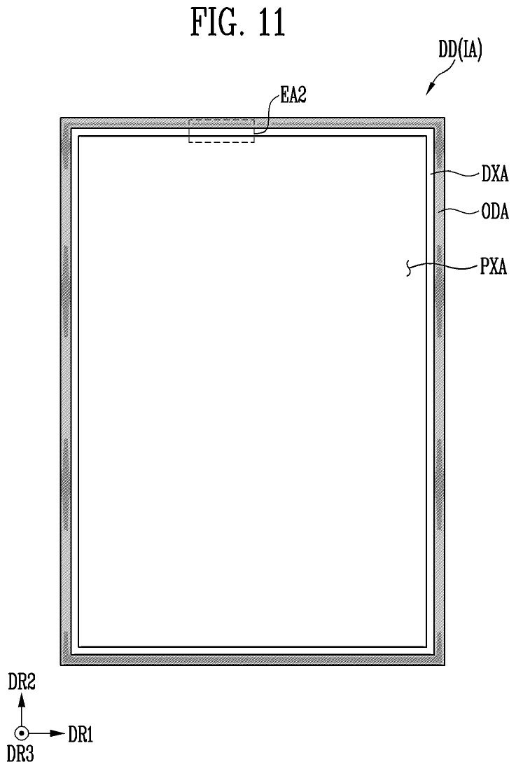

A display device DD including an outer-dam area ODA according to another embodiment will be described with reference to FIGS. 11 to 14. FIGS. 11 to 14 are schematic drawings illustrating a display device including an outer-dam area according to another embodiment.

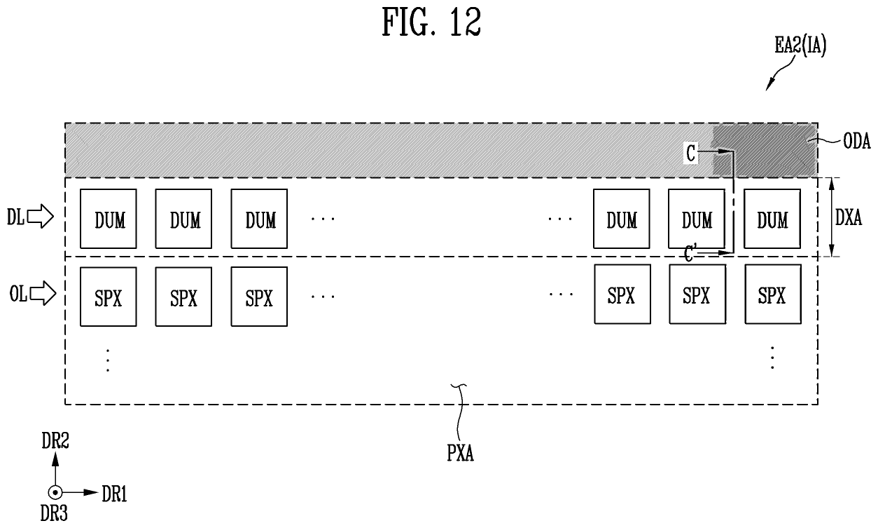

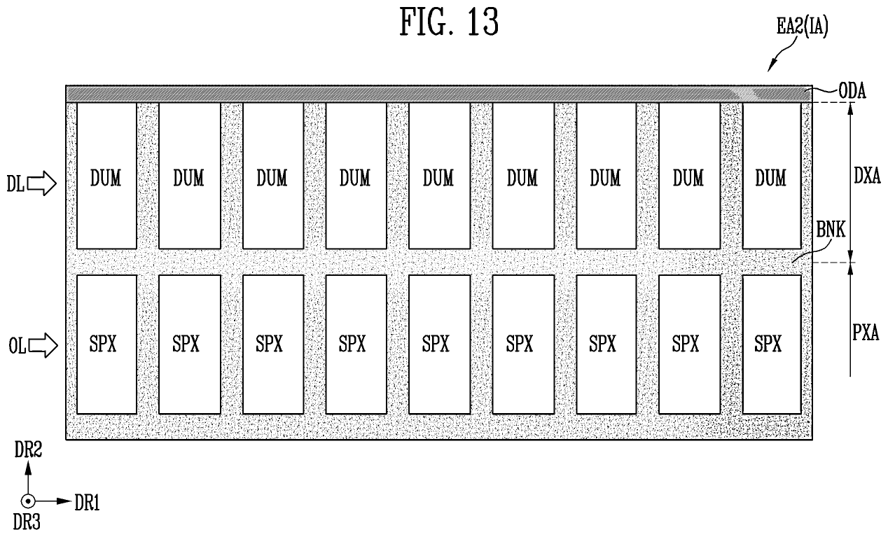

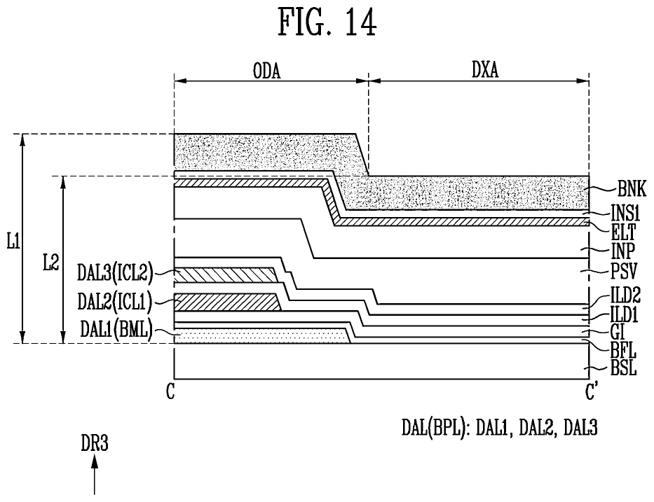

FIG. 11 is a schematic plan view illustrating a display device including an outer-dam area according to an embodiment. FIGS. 12 and 13 are schematic enlarged views of EA2 area of FIG. 11. FIG. 14 is a schematic cross-sectional view taken along line C-C′ of FIG. 12.

The display device DD according to the embodiment is different from the display device DD of FIGS. 8-10 in that the embodiment further includes a dummy pixel area DXA.

According to an embodiment, the dummy pixel area DXA may be disposed between the pixel area PXA and the outer-dam area ODA. The dummy pixel area DXA may be disposed inside the outer-dam area ODA.

The dummy pixel area DXA may surround at least a portion of the pixel area PXA in a plan view. The dummy pixel area DXA may be formed at a periphery of the pixel area PXA. According to an embodiment, the dummy pixel area DXA may be formed at the edge of the pixel area PXA.

According to an embodiment, the outer-dam area ODA may surround at least a portion of the dummy pixel area DXA in a plan view. The outer-dam area ODA may surround at least a portion of the edges of the dummy pixel area DXA in a plan view.

The dummy pixel area DXA may be directly adjacent to the pixel area PXA. The dummy pixel area DXA may be directly adjacent to the outer-dam area ODA.

Dummy pixels DUM may be disposed in the dummy pixel area DXA. The dummy line DL may be a dummy pixel row line or a dummy pixel column line disposed outside the pixel area PXA and adjacent to an edge of the internal area IA. For convenience of description, the drawings after FIG. 12 will be described based on an embodiment in which the dummy line DL is a dummy pixel row line.

According to an embodiment, the dummy pixels DUM may be disposed along the dummy line DL. The number of dummy lines DL is not particularly limited. For example, the number of dummy lines DL may be single or multiple.

According to an embodiment, the light emitting element LD may not be disposed in each of the dummy pixels DUM. For example, the bank BNK including the opening OPN may not be disposed in the area where the dummy pixels DUM are formed, and the bank BNK including the opening OPN may be disposed in the area where the sub-pixels SPX are formed.

Similar to the previous embodiment, as the dam formation line DAL is disposed in the outer-dam area ODA, the uppermost portion of the bank BNK in the outer-dam area ODA may be formed higher than the uppermost portion of the bank BNK in the dummy pixel area DXA.

For example, in the outer-dam area ODA, the upper surface of the bank BNK may be spaced apart from the base layer BSL by a first distance L1. In an area (e.g., dummy pixel area DXA) other than the outer-dam area ODA, the upper surface of the bank BNK may be spaced apart from the base layer BSL by a second distance L2. The first distance L1 may be greater than the second distance L2.

Accordingly, the protruding structure defined in the outer-dam area ODA may surround the edges of the pixel area PXA and the dummy pixel area DXA in a plan view.

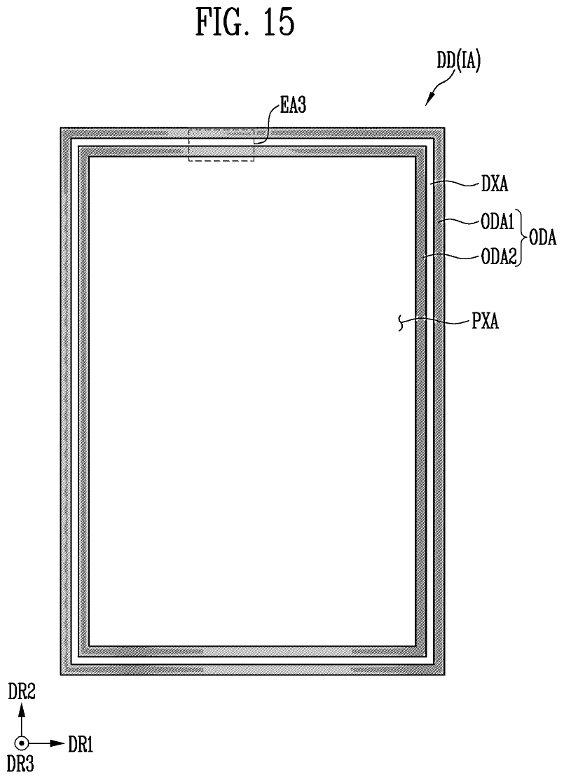

A display device DD including an outer-dam area ODA according to another embodiment will be described with reference to FIGS. 15 to 17. FIGS. 15 to 17 are schematic drawings illustrating a display device including an outer-dam area according to another embodiment.

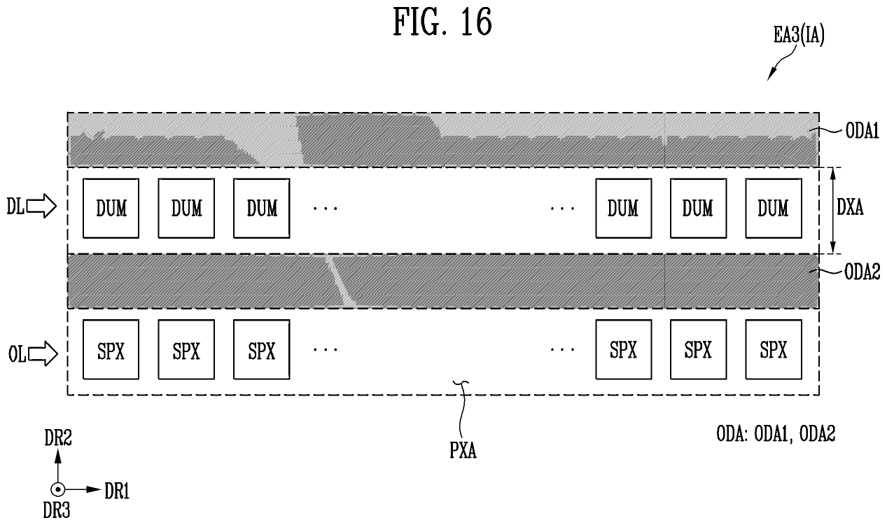

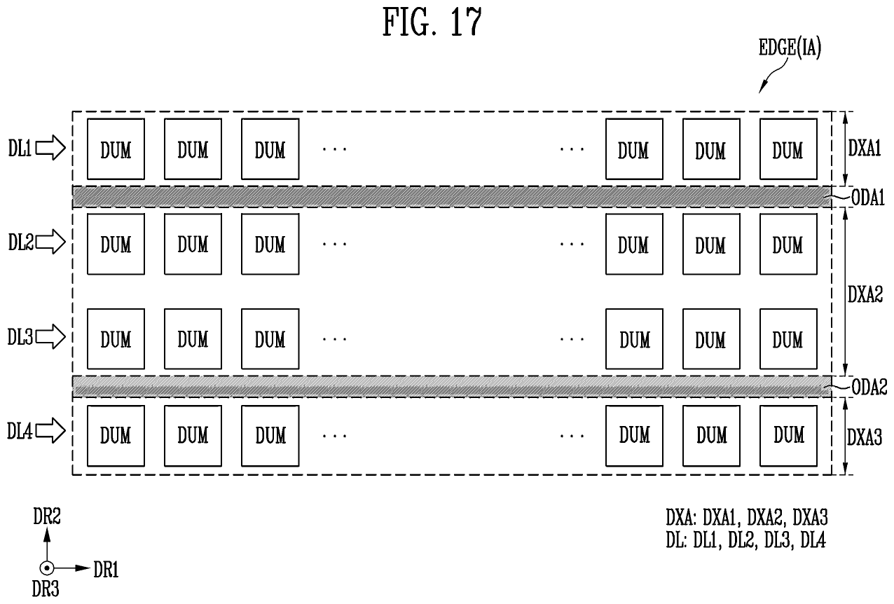

FIG. 15 is a schematic plan view illustrating a display device including an outer-dam area according to an embodiment. FIG. 16 is a schematic enlarged view of EA3 area. FIG. 17 schematically illustrates a structure in which the dummy pixel area according to an embodiment is disposed outside the outer-dam area.

The display device DD according to the embodiment may further include a dummy pixel area DXA but may be different from the display device DD according to the embodiment of FIGS. 11-14 in that the dummy pixel area DXA is disposed between the outer-dam areas ODA1 and ODA2.

According to an embodiment, the outer-dam area ODA may include multiple areas spaced apart from each other. For example, the outer-dam area ODA may include a first outer-dam area ODA1 and a second outer-dam area ODA2. The number of areas forming the outer-dam area ODA is not particularly limited.

In case that the outer-dam area ODA includes multiple areas spaced apart from each other, and the solvent SLV is supplied on the pixel-circuit layer PCL (e.g., base layer BSL), the outer-dam area ODA may more closely remove a space where the solvent SLV is accommodated. For example, even in case that some of the solvent SLV is moved beyond the second outer-dam area ODA2 to the second dummy pixel area DXA2, the movement of the moved solvent SLV may be restricted by the first outer-dam area ODA1.

According to an embodiment, the dummy pixel area DXA may be disposed between the first outer-dam area ODA1 and the second outer-dam area ODA2. For example, a first side of the dummy pixel area DXA may face the first outer-dam area ODA1, and a second side of the dummy pixel area DXA may face the second outer-dam area ODA2. According to an embodiment, the second outer-dam area ODA2 may be disposed between the pixel area PXA and the dummy pixel area DXA.

According to an embodiment, referring to FIG. 17 illustrating the edge area EDGE of the internal area IA, the dummy pixel area DXA may include two or more dummy lines DL. The outer-dam areas ODA may be disposed between the dummy lines DL, respectively. For example, the dummy lines DL may include a first dummy line DL1 (e.g., first dummy pixel row or first dummy pixel column), a second dummy line DL2 (e.g., second dummy pixel row or second dummy pixel column), a third dummy line DL3 (e.g., third dummy pixel row or third dummy pixel column), and a fourth dummy line DL4 (e.g., fourth dummy pixel row or fourth dummy pixel column).

According to an embodiment, two or more dummy lines DL2 and DL3 may be disposed between the outer-dam areas ODA1 and ODA2. The number of dummy lines DL formed between the outer-dam areas ODA1 and ODA2 is not particularly limited.

According to an embodiment, the first outer-dam area ODA1 may be disposed between the first dummy pixel area DXA1 in which the first dummy line DL1 is formed and the second dummy pixel area DXA2 in which the second and third dummy lines DL2 and DL3 are formed. The second outer-dam area ODA2 may be disposed between the second dummy pixel area DXA2 in which the second and third dummy lines DL2 and DL3 are formed and the third dummy pixel area DXA3 in which the fourth dummy line DLA is formed.

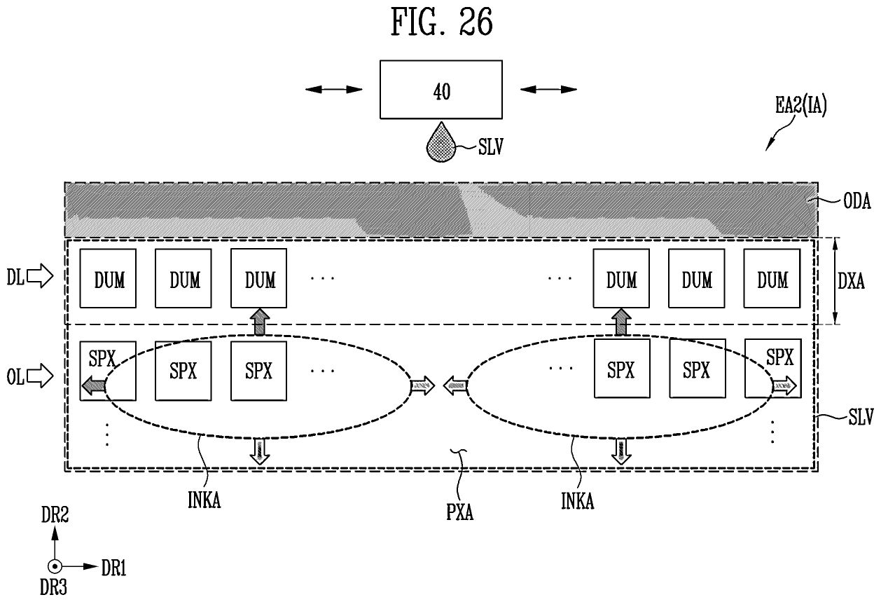

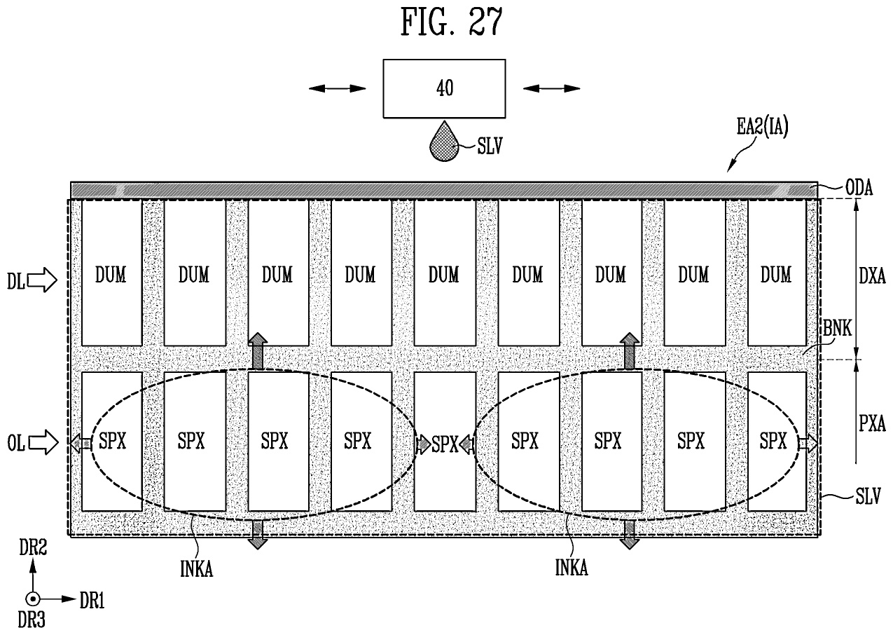

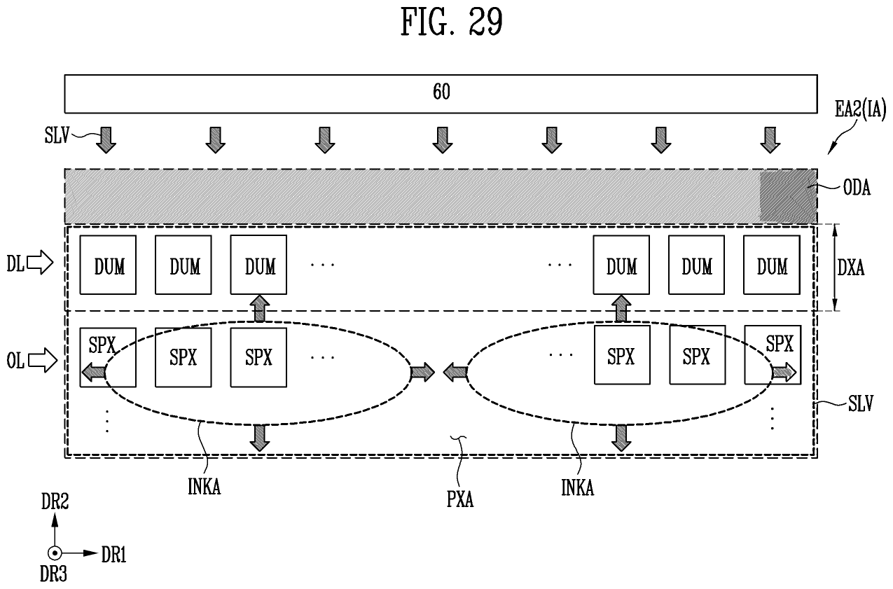

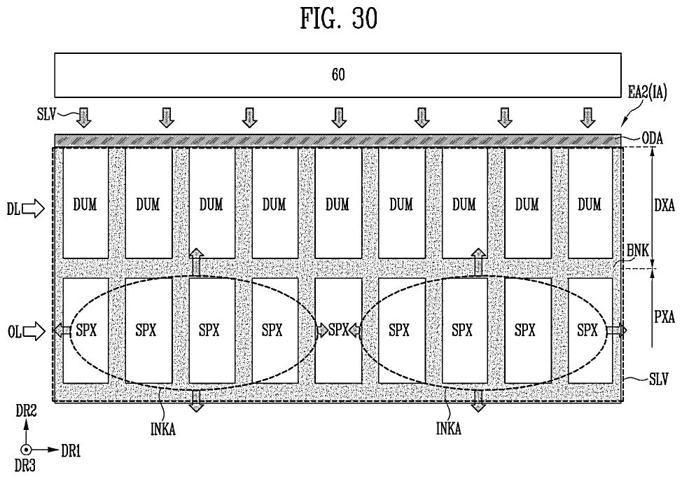

With reference to FIGS. 18 to 31, a method of manufacturing the display device DD according to an embodiment will be described. For convenience of description, duplicate description is briefly explained or not repeated. For convenience of description, a method of manufacturing the display device DD will be described based on the display device DD according to the embodiment described with reference to FIGS. 11 to 14.

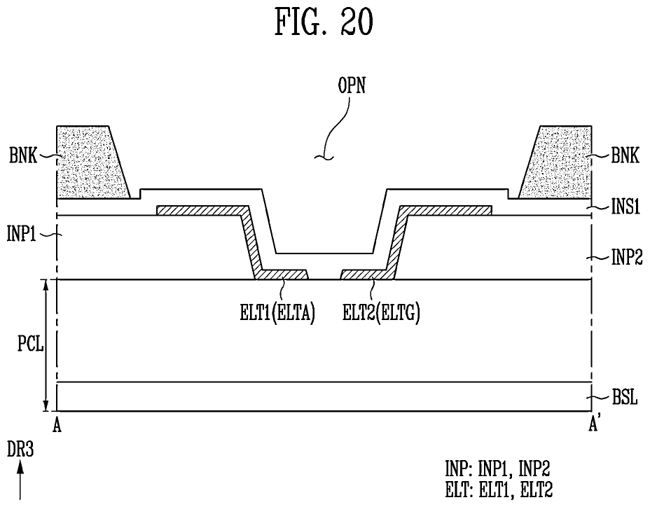

FIGS. 18 and 19 are flowcharts illustrating a manufacturing method of a display device according to an embodiment. FIGS. 20 to 31 are schematic drawings of each process step illustrating a manufacturing method of a display device according to an embodiment.

FIG. 18 illustrates steps of a manufacturing method of a display device DD according to an embodiment. FIG. 19 is a flowchart illustrating supplying a light emitting element LD (S200) according to an embodiment.

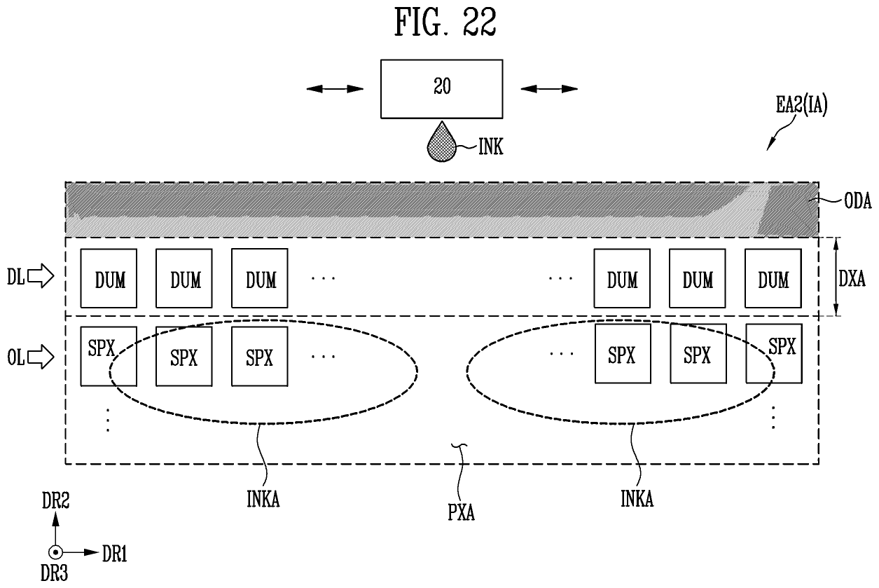

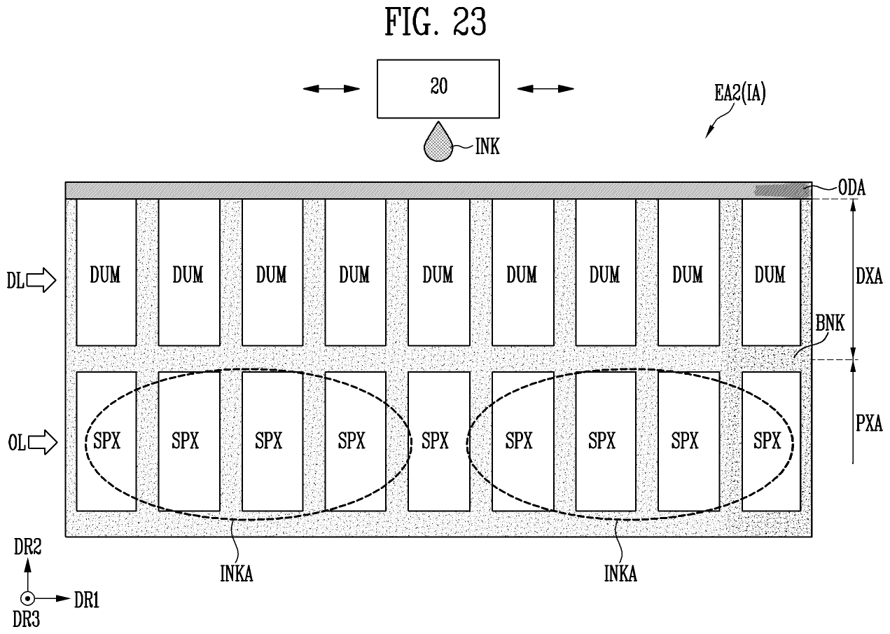

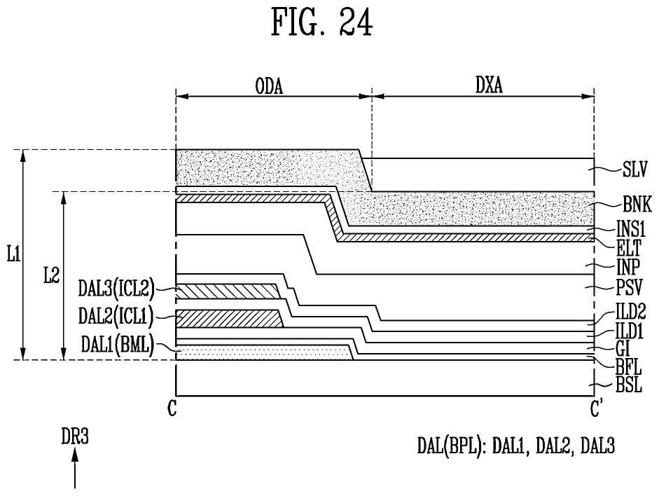

FIGS. 20, 21, 25, 28, and 31 may represent process steps based on the cross-sectional structure shown in FIG. 6. FIGS. 22, 26, and 29 may represent process steps based on the planar structure shown in FIG. 12. FIGS. 23, 27, and 29 may represent process steps based on the planar structure shown in FIG. 13. FIG. 24 may represent process steps based on the cross-sectional structure shown in FIG. 14.

Referring to FIG. 18, the method of manufacturing the display device DD according to an embodiment may include forming an alignment-electrode layer including a first alignment electrode and a second alignment electrode and a bank on the pixel-circuit layer (S100), supplying a light emitting element on a base layer (S200), aligning the light emitting element between the first alignment electrode and the second alignment electrode (S300), and forming a connection-electrode layer (S400).

Referring to FIG. 19, the supplying of the light emitting element on the base layer (S200) may include providing an ink including the light emitting element and a solvent (S220) and providing a solvent (S240).

Referring to FIGS. 18 and 20, in the forming the alignment-electrode layer including a first alignment electrode and a second alignment electrode and the bank on the pixel-circuit layer (S100), a pixel-circuit layer PCL may be manufactured, and the first alignment electrode ELTA, the second alignment electrode ELTG, and the bank BNK may be patterned on the pixel-circuit layer PCL.

A conductive layer or an insulating layer on the base layer BSL may be formed based on a process for manufacturing a semiconductor device. For example, the conductive layer or the insulating layer on the base layer BSL may be formed by a photolithography process and may be deposited by various methods (e.g., sputtering, chemical vapor deposition, etc.). The disclosure is not necessarily limited to a particular embodiment.

According to an embodiment, multiple base layers BSL may be provided, and the base layers BSL may be provided as a mother substrate coupled to each other. For example, the manufacturing method according to an embodiment may be applied to the mother substrate including the base layers BSL, and the base layers BSL may be separated and prepared into each display device DD.

In this step, lower lines BPL including the lower auxiliary electrode layer BML, the first interlayer conductive layer ICL1, and the second interlayer conductive layer ICL2 may be patterned on the base layer BSL.

As description above, the lower auxiliary electrode layer BML, the first interlayer conductive layer ICL1, and the second interlayer conductive layer ICL2 may be disposed to overlap with each other in a plan view in some areas where the outer-dam area ODA is to be formed.

In this step, insulating patterns INP may be patterned on the pixel-circuit layer PCL, and alignment-electrode layers ELT may be patterned on the insulating patterns INP. Accordingly, the first alignment electrode ELTA and the second alignment electrode ELTG may be disposed to be spaced apart from each other so that the light emitting elements LD can be aligned. A first insulating layer INS1 may be disposed on the alignment-electrode layer ELT, and a bank BNK including an opening OPN may be patterned on the first insulating layer INS1.

Referring to FIGS. 18, 19, and 21 to 23, in the supplying of the light emitting element on the base layer (S200), the providing of the ink including the light emitting element and the solvent (S220) may be performed.

In this step, the ink INK including the light emitting element LD and the solvent SLV may be supplied on the pixel-circuit layer PCL (e.g., base layer BSL). For example, the first printing apparatus 20 may eject the ink INK.

According to an embodiment, the solvent SLV may include an organic solvent. For example, the solvent SLV may be at least one of propylene glycol methyl ether acetate (PGMEA), dipropylene glycol n-propyl ether (DGPE), and triethylene gylcol n-butyl ether (TGBE). However, the disclosure is not limited thereto.

The first printing apparatus 20 may include an inkjet printer configured to eject fluid. For example, the first printing apparatus 20 may include a nozzle unit through which the ink INK is ejected, an ink channel fluidly connected to the nozzle unit, and an ink reservoir fluidly connected to the ink channel, and the printing apparatus 20 may move parallel to the pixel-circuit layer PCL. Accordingly, the first printing apparatus 20 may locally eject the ink INK to each of some areas of the pixel-circuit layer PCL.

In this step, the ink INK may be supplied to some areas where the pixel area PXA is to be formed. For example, the ink INK may be supplied locally to some areas of the pixel area PXA. The area to which the ink INK is supplied may be defined as the ink area INKA.

According to an embodiment, the concentration (e.g., number of light emitting elements LD per unit volume) of the light emitting elements LD included in the ink INK may be determined according to the number of the light emitting elements LD of each sub-pixel SPX based on the resolution, etc. of the display device DD to be manufactured. According to an embodiment, the ink area INKA may be not individually controlled based on each of the sub-pixels SPX, and only the solvent SLV may be supplied in the subsequent process, so the light emitting element LD included in the ink INK can be manufactured at a high concentration. Accordingly, the number of process steps in the inkjet printing process may be reduced and the process steps may be simplified.

Even in case that multiple base layers BSL are provided and the ink INK is ejected onto the motherboard, and each of the display devices DD to be manufactured is manufactured at a different resolution with each other, the manufacturing method according to the embodiment is suitable thereto. For example, a different number of light emitting elements LD may be relatively readily supplied to each of the mother substrates by the first printing apparatus 20.

The ink area INKA may entirely cover a single sub-pixel SPX (e.g., opening OPN for the sub-pixel SPX). For example, the ink area INKA may cover two or more sub-pixels SPX. The ink areas INKA may be spaced apart from each other to be formed in each of the areas. The ink areas INK may be formed to overlap the pixel area PXA in a plan view.

According to an embodiment, the first printing apparatus 20 may not eject the ink INK based on each of the sub-pixels SPX, and the first printing apparatus 20 may eject the ink INK to each of some areas of the pixel area PXA.

For example, the inkjet printing process ejecting the ink INK may not be controlled based on each sub-pixel SPX but may be controlled based on a local area in the pixel area PXA, and process convenience can be significantly improved.

For example, experimentally, in case that the inkjet printing process is performed based on each sub-pixel SPX, due to a hardware issue of the first printing apparatus 20, it may be difficult to finely control the movement of the first printing apparatus 20. However, the movement of the first printing apparatus 20 may be controlled based on a relatively wide area, and in the subsequent process, the light emitting elements LD may be moved so that the light emitting elements LD can be provided to each of the sub-pixels SPX. As a result, process efficiency may be improved, and process difficulty may be reduced.

According to an embodiment, the ink INK may be ejected so that the ink area INKA overlaps at least the pixel area PXA, and the ink area INKA may overlap or may not overlap the dummy pixel area DXA in a plan view.

According to an embodiment, the ink area INKA may not overlap the outer-dam area ODA in a plan view. For example, the inkjet printing process ejecting the ink INK may be controlled so that the ink INK is not supplied to the outer-dam area ODA.

Referring to FIGS. 18, 19, and 24 to 30, in the supplying the light emitting element on the base layer (S200), providing a solvent (S240) may be performed.

According to an embodiment, after ejecting the ink INK including the light emitting element LD, a process of ejecting the solvent SLV that is a fluid that does not substantially include the light emitting element LD may be separately performed.

As described above, the ink INK may be ejected based on an area rather than each of the sub-pixels SPX. The light emitting elements LD included in the ink INK may need to be moved to the opening OPN corresponding to each of the sub-pixels SPX.

According to an embodiment, as the providing of the solvent (S240) is performed, the light emitting elements LD may be moved to the opening OPN of each of the sub-pixels SPX. For example, the provided solvent SLV may fill at least a portion of the interior of the area surrounded by the outer-dam area ODA. According to an embodiment, the solvent SLV may be moved in the pixel area PXA, and a portion of the solvent SLV may be disposed in the dummy pixel area DXA.

For example, the providing of the solvent according to an embodiment (S240) may include providing the light emitting elements LD to the opening OPN of each of the sub-pixels SPX. Accordingly, the light emitting elements LD disposed in the ink area INKA may be moved to and disposed throughout the pixel area PXA. According to the embodiment, as the formation of the outer-dam area ODA and the solvent SLV is supplied, the light emitting element LD may be moved to the opening OPN of each sub-pixel SPX without the process of supplying the light emitting element LD for each sub-pixel SPX. Accordingly, the method of manufacturing the display device DD with improved process convenience may be provided.

During the providing the solvent according to the embodiment (S240) is performed, an alignment signal may be supplied to the first alignment electrode ELTA and the second alignment electrode ELTG defined in each of the sub-pixels SPX. For example, the alignment signal supplied in this step may form an electric field that maintains the position of the light emitting elements LD in some sub-pixels SPX. In the areas of at least some of the sub-pixels SPX, a position maintenance electric field may be formed to maintain the position of the light emitting elements LD, thereby preventing the light emitting elements LD from being excessively displaced. The number of light emitting elements LD for each sub-pixel SPX may be designed to be generally uniform.

According to the embodiment, the area to which the solvent SLV is supplied in this step may be defined based on a relatively large area. For example, the solvent SLV may be supplied entirely in the pixel area PXA. Experimentally, in case that the area where the ink INK is supplied is defined based on each of the sub-pixels SPX, the ink INK may be supplied in a relatively narrow area, so heights of the ink INK (e.g., droplet) may be uneven. For example, in a narrow area, the ink INK may have a lower height toward the outside. Due to this, the electric field for aligning the light emitting element LD may be formed non-uniformly in the subsequent process. However, according to the embodiment, the solvent SLV is supplied based on a large area, so the height of the entire ink INK may be generally uniform after the solvent SLV is supplied. The electric field for aligning the light emitting elements LD may be formed uniformly, thereby improving the degree of alignment of the light emitting elements LD.

According to an embodiment, the providing of the solvent (S240) may be performed in various ways.

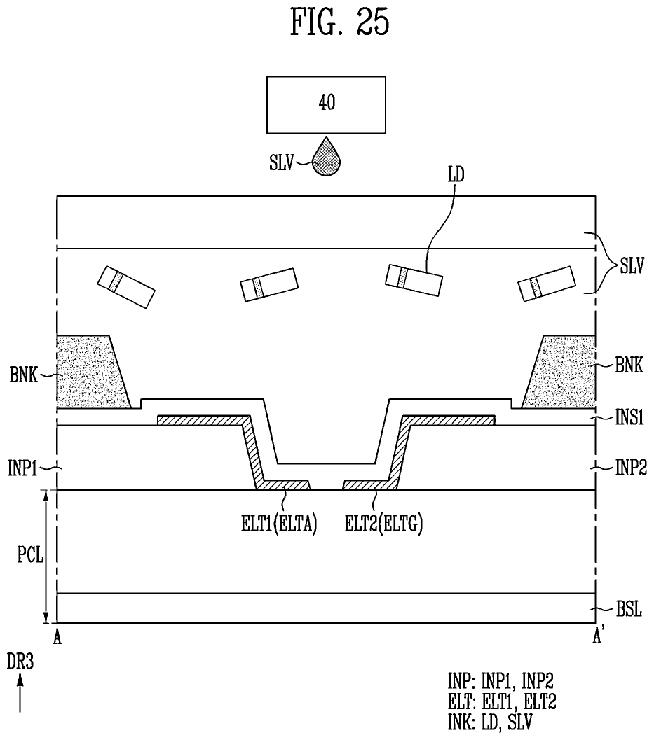

For example (see FIGS. 25 to 27), the providing of the solvent (S240) may be performed by the second printing apparatus 40. The second printing apparatus 40 may include an inkjet printer configured to eject fluid. For example, the second printing apparatus 40 may include a nozzle unit through which the solvent SLV is ejected, a solvent channel fluidly connected to the nozzle unit, and a solvent reservoir fluidly connected to the solvent channel, and the printing apparatus 40 may move parallel to the pixel-circuit layer PCL. Accordingly, the second printing apparatus 40 may eject the solvent SLV on the pixel-circuit layer PCL.

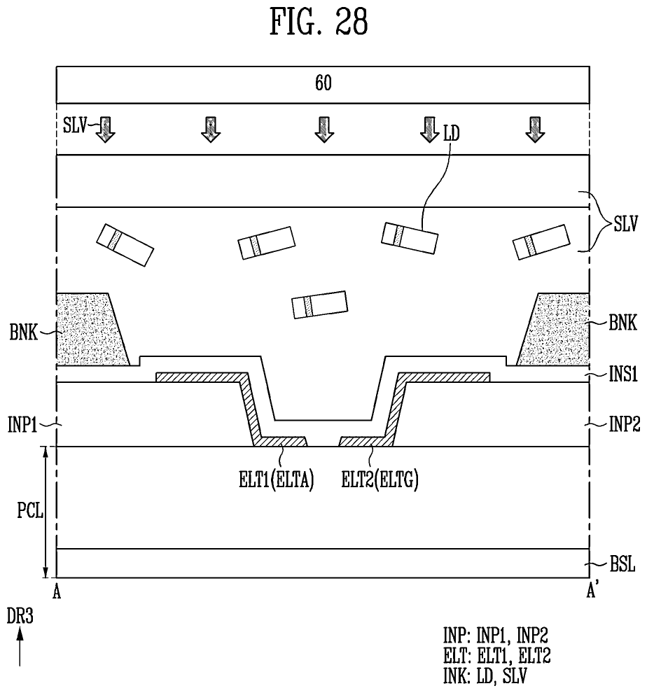

For example (see FIGS. 28 to 30), the providing of the solvent (S240) may be performed by the nozzle coater 60. The nozzle coater 60 may move using a gantry adjacent to the base layer BSL (or mother substrate) and may eject the solvent SLV to each of different areas as the nozzle coater 60 moves in a direction. In case that the nozzle coater 60 is used, it can be relatively simple to maintain process equipment, and relatively high process productivity may be realized. The nozzle coater 60 may supply the solvent SLV to a greater area at once than the second printing apparatus 40.

In case that the nozzle coater 60 is used, the light emitting element LD may be not mixed with the solvent SLV sprayed by the nozzle coater 60, so the solvent SLV may have viscosity suitable for the nozzle coater 60.

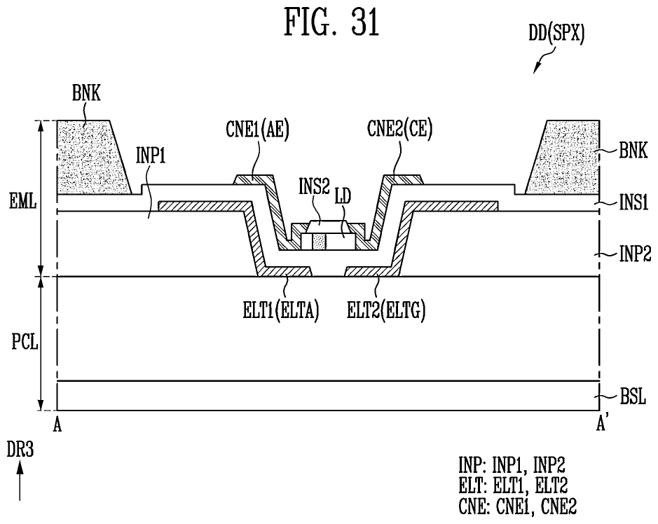

Referring to FIGS. 18 and 31, in the aligning of the light emitting element between the first and second alignment electrodes (S300), an alignment signal may be applied to the first alignment electrode ELTA and the second alignment electrode ELTG. The light emitting elements LD may be aligned based on the electric field formed accordingly.

Referring to FIGS. 18 and 31, the forming of a connection-electrode layer may be performed (S400), so that the connection-electrode layer CNE may be electrically connected to each end of the light emitting elements LD.

For example, before this step is performed, the solvent SLV may be removed (e.g., by drying process), and the first connection electrode CNE1 and the second connection electrode CNE2 may be patterned. According to an embodiment, the second insulating layer INS2 may be disposed on the light emitting element LD before the connection-electrode layer CNE is patterned.

Thereafter, according to an embodiment, the constituent elements on the light emitting layer EML may be sequentially disposed, and the display device DD according to the embodiment may be manufactured.

The above description is an example of technical features of the disclosure, and those skilled in the art to which the disclosure pertains will be able to make various modifications and variations. Therefore, the embodiments of the disclosure described above may be implemented separately or in combination with each other.

Therefore, the embodiments disclosed in the disclosure are not intended to limit the technical spirit of the disclosure, but to describe the technical spirit of the disclosure, and the scope of the technical spirit of the disclosure is not limited by these embodiments. The protection scope of the disclosure should be interpreted by the following claims, and it should be interpreted that all technical spirits within the equivalent scope are included in the scope of the disclosure.

What is claimed is:

1. A display device including an internal area and a peripheral area surrounding at least a portion of the internal area, comprising:
a pixel-circuit layer disposed on a base layer and including lower lines, at least a portion of the lower lines forming a pixel circuit; and
sub-pixels disposed on the pixel-circuit layer and including a light emitting element electrically connected to the pixel circuit, wherein the internal area includes:
a pixel area on which the sub-pixels are disposed; and
an outer-dam area formed at a periphery of the pixel area, and
in the outer-dam area, at least another portion of the lower lines are stacked in a thickness direction of the base layer to form a protruding structure.

2. The display device of claim 1, wherein the outer-dam area surrounds an edge of the pixel area and forms a loop structure in a plan view.

3. The display device of claim 1, further comprising:
a bank disposed on the pixel-circuit layer, wherein
an upper surface of the bank is spaced apart from the base layer in the outer-dam area by a first distance, and is spaced apart from the base layer in the pixel area by a second distance, and
the first distance is greater than the second distance.

4. The display device of claim 1, further comprising
a first electrode and a second electrode disposed on the pixel-circuit layer and spaced apart from each other, wherein
the light emitting element is disposed between the first electrode and the second electrode.

5. The display device of claim 4, wherein the light emitting element is not disposed in the outer-dam area so that the sub-pixels are not formed in the outer-dam area.

6. The display device of claim 1, wherein
the lower lines include:
a lower auxiliary electrode layer disposed on the base layer, at least a portion of which forms a first dam formation line;
a first interlayer conductive layer disposed on the lower auxiliary electrode layer, at least a portion of which forms a second dam formation line; and
a second interlayer conductive layer disposed on the first interlayer conductive layer, at least a portion of which forms a third dam formation line, and
the first dam formation line, the second dam formation line, and the third dam formation line form the protruding structure.

7. The display device of claim 1, further comprising:
a dummy pixel area disposed between the pixel area and the outer-dam area.

8. The display device of claim 7, wherein
the light emitting element is not disposed in the dummy pixel area, and
a dummy line is disposed in the dummy pixel area.

9. The display device of claim 8, wherein
the outer-dam area includes a first outer-dam area and a second outer-dam area spaced apart from each other, and
at least a portion of the dummy pixel area is disposed between the first outer-dam area and the second outer-dam area.

10. The display device of claim 9, wherein
the dummy pixel area includes a first dummy pixel area, a second dummy pixel area, and a third dummy pixel area, which are spaced apart from each other,
the first outer-dam area is disposed between the first dummy pixel area and the second dummy pixel area, and
the second outer-dam area is disposed between the second dummy pixel area and the third dummy pixel area.

11. A display device comprising:
a pixel-circuit layer disposed on a base layer, at least a portion of the pixel-circuit layer including a pixel circuit;
a light emitting element layer disposed on the pixel-circuit layer and including a light emitting element electrically connected to the pixel circuit and a bank surrounding at least a portion of an area on which the light emitting element is disposed;
a pixel area on which the light emitting element is disposed;
a dummy pixel area surrounding at least a portion of the pixel area in a plan view and on which the light emitting element is not disposed; and
an outer-dam area surrounding at least a portion of the dummy pixel area in a plan view, wherein
an upper surface of the bank is spaced from the base layer by a first distance in the outer-dam area and is spaced from the base layer by a second distance in the dummy pixel area, and
the first distance is greater than the second distance.

12. A manufacturing method of a display device including an internal area and a peripheral area surrounding at least a portion of the internal area, comprising:
forming an alignment-electrode layer including a first alignment electrode and a second alignment electrode and a bank on a pixel-circuit layer;
supplying a light emitting element on the pixel-circuit layer; and
aligning the light emitting element between the first alignment electrode and the second alignment electrode, wherein
the pixel-circuit layer includes a base layer and lower lines on the base layer,
the internal area includes an outer-dam area formed at an edge of the internal area, and
in the outer-dam area, at least a portion of the lower lines are stacked in a thickness direction of the base layer to form a protruding structure.

13. The manufacturing method of claim 12, wherein the supplying of the light emitting element includes:
providing ink including the light emitting element on the pixel-circuit layer; and
providing a solvent on the pixel-circuit layer.

14. The manufacturing method of claim 13, wherein
the forming of the bank includes patterning the bank to form openings,
the providing of the ink includes forming an ink area on which the ink is disposed, and
the ink area covers the openings.

15. The manufacturing method of claim 14, wherein
the providing of the solvent includes moving the light emitting element to each of the openings, and
a movement of the light emitting element is restricted by the protruding structure.

16. The manufacturing method of claim 13, wherein in the providing of the solvent, an alignment signal is supplied to the first alignment electrode and the second alignment electrode to form an electric field for maintaining a position of the light emitting element.

17. The manufacturing method of claim 13, wherein
the internal area includes a pixel area, and
the providing of the solvent includes supplying the solvent entirely in the pixel area.

18. The manufacturing method of claim 13, wherein
the providing of the ink is performed by a first printing apparatus, and
the providing of the solvent is performed by a second printing apparatus.

19. The manufacturing method of claim 13, wherein
the providing of the ink is performed by a printing apparatus,
the providing of the solvent is performed by a nozzle coater.

20. The manufacturing method of claim 12, further comprising:
patternin a connection-electrode layer including a first connection electrode and a second connection electrode electrically connected to the light emitting element.
